(19) United States
(12) Patent Application Publication
(10) Pub. No.: US 2016/0044841 A1
(43) Pub. Date: Feb. 11, 2016

(54) MAGNETIC SHIELDS

(71) Applicant: Lisa Chamberlain, Rockton, IL (US)

(72) Inventor: Lisa Chamberlain, Rockton, IL (US)

(21) Appl. No.: 14/455,005

(22) Filed: Aug. 8, 2014

(51) Int. Cl. H05K 9/00; A41D 13/00

(52) U.S. Cl. CPC H05K 9/0088; A41D 13/0002

(57) ABSTRACT

The present invention relates generally to protecting devices from the detrimental effects of magnetic fields and electromagnetic fields emitted by ambient sources. More particularly, the present invention provides magnetic shields between sensitive devices and portable magnetic and electromagnetic field sources.

### CROSS REFERENCE TO RELATED APPLICATIONS

The present application claims priority to U.S. Provisional Patent Application 61/864,326, filed Aug. 9, 2013, which is incorporated by reference herein in its entirety.

### FIELD OF THE INVENTION

The present invention relates generally to protecting devices from the detrimental effects of magnetic fields and electromagnetic fields emitted by ambient sources. More particularly, the present invention provides magnetic shields between sensitive devices and portable magnetic and electromagnetic field sources.

### BACKGROUND

Users of a diversity of worn and implanted devices are warned by manufacturers and user's groups that worn and implanted devices may be sensitive to magnetic and electromagnetic fields that may result in mechanical malfunction, reprogramming, and other interference with intended uses. Accordingly, users of sensitive devices are warned to avoid contact with magnetic and electromagnetic field sources, and to maintain a suggested distance between a sensitive device and a magnetic or electromagnetic field source that may vary widely between sensitive devices and field sources. However, sources of magnetic and electromagnetic fields are commonplace, and are rarely labelled to warn users of sensitive devices. Accordingly, children and adults may have unknowing exposure to portable, household and consumer sources of magnetic and electromagnetic fields such as those found in home appliances, hand-held communication instruments, games, toys, and computers. Users of sensitive devices may not even be aware or on notice that they should take action and move away, or even be able to move away in all circumstances. As well, maintaining a suggested distance between a sensitive device and a field source may deprive users of many advantages provided by magnetic and electromagnetic field sources, thereby delaying learning and enrichment, and becoming stigmatized when compared to others who are not similarly encumbered.

Clearly there is a need for methods, compositions, systems and kits that provide magnetic and electromagnetic shields to sensitive devices that are effective at preserving the sensitive device's intended operations, are versatile in shielding a diversity of sensitive devices from a diversity of magnetic or and electromagnetic field sources, are easily applied to magnetic and electromagnetic field sources either as a built-in or as add-on, post-acquisition component or appliance, and easily positioned between a sensitive device and a magnetic and electromagnetic field source,

It will be understood by those skilled in the art that one or more aspects of this invention can meet certain objectives, while one or more other aspects can lead to certain other objectives. Other objects, features, benefits and advantages of the present invention will be apparent in this summary and descriptions of the disclosed embodiment, and will be readily apparent to those skilled in the art. Such objects, features, benefits and advantages will be apparent from the above as taken in conjunction with the accompanying figures and all reasonable inferences to be drawn therefrom.

### SUMMARY OF THE INVENTION

The present invention relates generally to protecting devices from the detrimental effects of magnetic fields and electromagnetic fields emitted by ambient sources. More particularly, the present invention provides magnetic shields between sensitive devices and portable magnetic and electromagnetic field sources.

In some embodiments, the present invention provides a method of protecting a sensitive device from a magnetic or electromagnetic field source, comprising determining a magnetic or electromagnetic field strength threshold below which the device is not sensitive to a magnetic or electromagnetic field wherein the device is a worn or an implanted device, determining a magnetic or electromagnetic field strength of the magnetic or electromagnetic field source wherein the magnetic or electromagnetic field source is a portable or household magnetic or electromagnetic field source, selecting and sizing a magnetic or electromagnetic shield to shield the sensitive device from the magnetic or electromagnetic field source wherein the shield comprises an alloy, and applying the shield to a magnetic or electromagnetic field source. In certain embodiments, the shield comprises a coating on the alloy. In further embodiments, the shield comprises two or more alloy layers. In still further embodiments, the two or more alloy layers are separated by one or more spacers. In other embodiments, the two or more alloy layers differ in shapes and dimensions. In particular embodiments the two or more alloy layers differ in composition. In some embodiments, the shield comprises a covering. In other embodiments, the alloy is folded, pleated or corrugated. In preferred embodiments, the shield is a magnetic or electromagnetic field source case. In certain embodiments, determining a magnetic or electromagnetic field strength threshold below which a device is not sensitive to a magnetic or electromagnetic field comprises measuring a threshold, acquiring a threshold from a database, or acquiring a threshold from a device manufacturer. In other embodiments, determining a magnetic or electromagnetic field strength of a magnetic or electromagnetic field source comprises measuring a field strength, acquiring a field strength from a database, or acquiring a threshold from a field source manufacturer.

In some embodiments, the present invention provides a method of protecting a sensitive device from a magnetic or electromagnetic field source, comprising determining a magnetic or electromagnetic field strength threshold below which the device is not sensitive to the magnetic or electromagnetic field wherein the device is a worn or an implanted device, determining a magnetic or electromagnetic field strength of the magnetic or electromagnetic field source wherein the magnetic or electromagnetic field source is a portable or household magnetic or electromagnetic field source, selecting and sizing a magnetic or electromagnetic shield to shield the sensitive device from the magnetic or electromagnetic field source wherein the shield comprises an alloy, and positioning the shield between the sensitive device and the magnetic or electromagnetic field source. In some embodiments, the shield comprises a coating on the alloy.

In other embodiments, the shield comprises two or more alloy layers. In further embodiments, the two or more alloy layers are separated by one or more spacers. In still further embodiments the two or more alloy layers differ in shapes and dimensions. In certain embodiments, the two or more alloy layers differ in composition. In some embodiments, the shield comprises a covering.

In preferred embodiments, the alloy is folded, pleated or corrugated. In particular embodiments the shield comprises a magnetic or electromagnetic field sensor and a visual and/or acoustic magnetic or electromagnetic field alert. In some embodiments, the positioning comprises positioning the shield in a garment, in a pouch or sleeve, or on a lanyard. In certain embodiments, determining a magnetic or electromagnetic field strength threshold below which a device is not sensitive to a magnetic or electromagnetic field comprises measuring a threshold, acquiring a threshold from a database, or acquiring a threshold from a device manufacturer. In other embodiments, determining a magnetic or electromagnetic field strength of a magnetic or electromagnetic field source comprises measuring a field strength, acquiring a field strength from a database, or acquiring a threshold from a field source manufacturer.

In some embodiments, the present invention provides a method of protecting a sensitive device from a magnetic and an electromagnetic field source, comprising determining a magnetic and electromagnetic field strength threshold below which the device is not sensitive to the magnetic and electromagnetic field wherein the device is a worn or an implanted device, determining a magnetic and electromagnetic field strength of the magnetic and the electromagnetic field source wherein the magnetic and the electromagnetic field source is a portable or household magnetic and electromagnetic field source, selecting and sizing a magnetic and electromagnetic shield to shield the sensitive device from the magnetic and electromagnetic field source wherein the shield comprises an alloy, and positioning the shield between the sensitive device and the magnetic and electromagnetic field source. In certain embodiments, determining a magnetic or electromagnetic field strength threshold below which a device is not sensitive to a magnetic or electromagnetic field comprises measuring a threshold, acquiring a threshold from a database, or acquiring a threshold from a device manufacturer. In other embodiments, determining a magnetic or electromagnetic field strength of a magnetic or electromagnetic field source comprises measuring a field strength, acquiring a field strength from a database, or acquiring a threshold from a field source manufacturer.

In some embodiments, the present invention provides a method of protecting a sensitive device from a magnetic or electromagnetic field source comprising selecting a magnetic shield wherein said shield reduces the magnetic or electromagnetic field strength of a magnetic or electromagnetic field source to a threshold below which said device is not sensitive to said magnetic and electromagnetic field, and applying the shield to the magnetic or electromagnetic field source. In certain embodiments, the magnetic or electromagnetic field source is a permanent magnet, a computer, a cell phone, a SmartPhone® (e.g., a portable phone with internet access), an audio source, a video source, a toy, a game, a learning aid, a musical instrument, a health care source, or a household appliance. In further embodiments, the sensitive device is a sensitive neurologic device or a sensitive programmable neurologic device. In still further embodiments the sensitive neurologic device is a ventriculo-peritoneal shunt, a vagal nerve stimulator, a deep brain stimulator, a spinal cord stimulator, or a neurologic electroencephalogram monitor. In other embodiments, the sensitive device is a sensitive cardiac device or a sensitive programmable cardiac device. In some embodiments, the sensitive cardiac device is a defibrillator, a cardio-verter, a ventricular assist device or a cardiac monitor. In other embodiments, the sensitive device is an insulin pump, a drug infusion pump, a cochlear or hearing implant, or a prosthetic device.

In some embodiments, the present invention provides a composition comprising one or more layers of magnetic shield alloy, one or more magnetic shield alloy coatings, one or more magnetic shield coverings, and one or more fasteners comprising two or more strips of plastic sheet wherein at least one strip provides loops and at least one strip provides flexible hooks, wherein said loop and hook strips removably adhere when pressed together. In some embodiments, at least one of the one or more layers of magnetic shield alloy is corrugated. In particular embodiments, the composition further comprises a magnetic or electromagnetic field sensor. In preferred embodiments the composition comprises a magnetic or electromagnetic field alert. In some embodiments, the dimensions and shape of the composition are configured to protect a sensitive neurologic device, a sensitive programmable neurologic device, a ventriculo-peritoneal shunt, a vagal nerve stimulator, a deep brain stimulator, a spinal cord stimulator, a neurologic electroencephalogram monitor, a sensitive cardiac device, a sensitive programmable cardiac device, a defibrillator, a cardio-verter, a ventricular assist device, a cardiac monitor, an insulin pump, a drug infusion pump, a cochlear or hearing implant, or a prosthetic device. In other embodiments, the dimensions and shape of the composition are configured to shield a permanent magnet, a computer, a cell phone, a SmartPhone®, an audio source, a video source, a toy, a game, a learning aid, a musical instrument, a health care magnetic or electromagentic field source, or a household appliance.

In some embodiments, the present invention provides a composition comprising a wearable garment, one or more layers of magnetic shield alloy, one or more magnetic shield alloy coatings, one or more magnetic shield coverings, and one or more fasteners comprising two or more strips of plastic sheet wherein at least one strip provides loops and at least one strip provides flexible hooks, wherein said loop and hook strips removably adhere when pressed together.

In some embodiments, the present invention provides a composition, comprising or more layers of magnetic shield alloy, one or more magnetic shield alloy coatings, one or more magnetic shield coverings, and a case for a magnetic or electromagnetic field source. In certain embodiments, the magnetic field source is a permanent magnet. In other embodiments, the electromagnetic field source is a portable electronic electromagnetic field source.

### DETAILED DESCRIPTION

### I. Introduction

The present invention relates generally to protecting devices from the detrimental effects of magnetic fields and electromagnetic fields emitted by ambient sources. More particularly, the present invention provides magnetic shields between sensitive devices and portable magnetic and electromagnetic field sources.

In some embodiments, the present invention provides protective shields against magnetic fields that arise from portable and ambient sources. A unit of measurement of a magnetic field is the gauss, abbreviated as G or Gs. One gauss is defined as one maxwell per square centimeter. For example, the field strength of a typical refrigerator magnet is 50-600 gauss, of a small iron magnet 100 gauss, of a small neodymium-iron-boron (NIB) magnet 2000 gauss. Another unit of measurement of a magnetic field is the tesla (T). One gauss equals 1×10⁻⁴ tesla (100 μT). The strength of a magnetic field is measured by gaussmeters and magnetometers. A magnetic field may be static arising, for example, from a permanent magnet. The magnetic field effect of a permanent magnet is directly proportional to the strength of the magnet, and inversely proportional to the distance of the magnet from the site of measurement. Magnetic fields are also produced by moving electric charges. Electromagnetic interference (EMI) is a disturbance that affects an electrical circuit due to either electromagnetic induction or electromagnetic radiation from an external source. EMI in the radio frequency is termed radio-frequency interference (RFI). A magnetic disturbance may directly disable or trigger a pump, switch or other mechanical component of a device. A magnetic disturbance may also interrupt, obstruct, or impair the performance of an electric circuit in, for example, the programmable hardware and software of a processor. Integrated circuits may be affected by EMI, may be a source of EMI, or both. Magnetic interference with the operative performance of a device may be coincidental or intentional. In some embodiments of the present invention, devices are configured to be sensitive to external magnetic fields so that a user may modify their function as desired by, for example, intentional switching or re-reprogramming. By controlling sensitive devices using electromagnetic signals, the devices may be calibrated or adjusted without the need for additional interventions. However, the ability to control devices with electromagnetic signals may make them susceptible to unintended adjustment by portable magnetic field sources. In certain embodiments, the present invention provides magnetic shield compositions and methods for companion magnet field sources. In some embodiments, two or more devices with shared, overlapping, or exclusive functions by the same user may be shielded from one another.

### II. Magnetic Field Sensitive Devices

In some embodiments, compositions, methods, kits and systems of the present invention may be used to protect a diversity of devices sensitive to the detrimental effects of magnetic fields emitted by ambient and portable sources. In some embodiments, a protected device may be an implantable or external device. In certain embodiments, an implantable device is a ventriculo-peritoneal (VP) shunt. VP shunts may have settings that may be altered from electromagnetic signals of greater than 90 G. Common household items may emit magnetic field levels greater than 90 G, including, for example, lap top computers which may generate over 300 G, cell phones, speakers in children's toys, and the like that may cause a VP shunt to open, close or otherwise malfunction.

In some embodiments, a protected device may be an implantable or external cardiac device, for example, a cardiac pacemaker, an implantable cardio-verter-defibrillator (ICD), a congestive heart failure device, a ventricular assist device (VAD), an artificial heart, and the like. Users of these devices are advised to avoid direct contact and proximity to avoid magnetic fields greater than 10 G, including for example, neodymium magnets, iPads®, refrigerators, refrigerator magnets, cellphones, portable DVD players, children's toys containing magnets or speakers, MP3®, player and other headphones (100 G-200 G at 2 cm), and the like. Implantable cardiac devices are often configured with magnetically sensitive components to intentionally alter the function of the device by, for example, superimposed application of a magnet to a device to activate or inactivate performance, suspend therapy or disable sensing. Accordingly, unintended EMI may cause ICD reprogramming, inhibition or triggering of pacing, battery depletion, damage to internal circuitry, misinterpretation of EMI noise, and inappropriate therapy.

In some embodiments, a protected device may be an implantable or external neurologic device, for example, a vagal nerve stimulator (VNS). A VNS stimulates at pre-set intervals and may be adjustable for stimulation on-time, stimulation off-time, output current, frequency, and pulse width, typically providing a 0.5-millisecond pulse repeated at 10-30 Hz for 30 sec, every 150 to 300 seconds. In certain embodiments, the present invention provides a protective shield to the VNS from magnetic fields emitted by ambient and portable sources. As used herein, “portable” refers to magnetic field sources that may be carried or moved by a person without assistance, or without a contrivance for lifting and moving. A programming wand may communicate with a generator via radio frequency (RF) signals to vary output current, frequency, pulse width, and stimulation off and on time. As well, a 50 G bar magnet may be used to deliver a burst of vagal stimulation, or to inhibit output, depending on whether the magnet is placed transiently or for a prolonged duration over the generator at, for example, a one inch distance. For example, the hand-held magnet can be used to initiate the stimulator when an aura is felt or at seizure onset, provide on-demand stimulation, temporarily inhibit stimulation, reset the pulse generator and processor, and test pulse generator function. Users may note that a control magnet inadvertently affects VNS function, affects sensitive electronic equipment, attracts environmental metal objects, and is uncomfortable and unattractive to wear. In other embodiments, the present invention provides a magnetic field protective case for a VNS magnet. In further embodiments, the magnet is worn in a protective shield case on, for example a belt, a strap, a band, a harness, an article of clothing, a backpack, or other garment or larger case.

In some embodiments of the present invention, the device protected from the detrimental effects of a magnetic field emitted by a portable source is, for example, an incontinence device, a bone growth stimulator, a gastric pacemaker, a prosthetic device, a hearing implant or a cochlear implant. In other embodiments, the device protected from the detrimental effects of a magnetic field emitted by a portable source is an implantable or external monitor, for example a cardiac Holter rhythm monitor, and electroencephalogram monitor, a medical sensor that is worn, or a medical sensor that is implanted that is sensitive to magnetic and electromagnetic interference. In certain embodiments, the protected device is a drug infusion pump comprising, for example, a pain medication pump, a hormone pump, or an insulin pump that maybe programmable by magnetic signal input.

In some embodiments of the present invention, the device protected from the detrimental effects of a magnetic field emitted by a portable source is, for example, a cell phone, a smart phone, a global positioning system (GPS) unit, a radiation monitor, a calculator, a weather meter, a hand-held computer and the like.

### III. Magnetic Field Sources

In some embodiments, compositions, methods, kits and systems of the present invention may be used to shield devices sensitive to the detrimental effects of magnetic fields emitted by a diversity of portable and ambient sources. In certain embodiments, magnetic field sources comprise permanent magnets including, for example, home magnets, reprogramming magnets, agricultural magnets, industrial magnets, and clothing, garment and shoe magnets, speaker and microphone magnets, and neodymium and ceramic craft magnets. In other embodiments, magnetic field sources comprise generators of electronic magnetic fields including, for example, computers, laptop computers, iPad®, iPhone®, iPod®, cell phones, cordless phones, radios, CD players, DVD players, TVs, Tablets®, Nooks®, and Kindle®, readers, MP3 headphones, buds and other headphones, clocks, and play stations, for example, PlayStations®, Nintendo®, and hand-held gaming systems. In further embodiments, magnetic field sources comprise generators of magnetic fields in toys with speakers, dolls, puzzles, books, learning aids, and musical instruments often with magnetic fields of 90 G and greater. In still further embodiments, magnetic field sources comprise generators of magnetic fields in health care, for example, electro-cautery, imaging, nerve and excitable tissue stimulation and recording. In particular embodiments, magnetic field sources comprise ambient generators of magnetic fields including, for example, appliances, magnetometers, transformers, ultrasonic devices, heating pads, wireless devices, baby monitors, electric blankets, and public address systems.

### IV. Magnetic Shield Compositions

In some embodiments, the present invention provides protective shields against magnetic fields comprising peak saturation, soft, nickel-iron alloys including, for example, temperature compensator alloys Hy-Ra “49”®, HyMu 77®, HyMu 77®, HyMu “80”® (“MAGNETSHIELD™”), Hipernom®, HyMu “80” Mark II®, and HyMu “800”® and “800” A®, although any other suitable material may be used without departing from the invention. Alloys are provided in varying thickness from 0.004″ to 0.062″ with greater absorption generally observed at greater thicknesses, although similar thicknesses may vary in attenuation between different alloys and manufacturers, for example, between Peak Saturation Alloy MAGNETSHIELD™ (Less EMF Inc.) and HyMu “80”® (National Electronic Alloy Inc.) In general, greater thickness is also associated with small increases in weight per unit surface area and decreased pliability. In particularly preferred embodiments, the present invention provides magnetic shields comprising 0.01-0.0154″ National Electronic Alloys (also available from Less EMF Inc.) HyMu “80”® (“MAGNETSHIELD™”) (also known as “Permalloy®”, “HyMu “80”®”, “MAG 7904®”, “MIL N 14411 C®”, “COMP. 1®” or “ASTM A753-78®”) comprising 80% NI, 5% MO, 0.5% Si, 0.02% CU, and the remaining balance is Fe, with extremely peak initial and maximum permeability, very low coercive force and minimum hysteresis loss. In some embodiments, “MAGNETSHIELD™” is provided as a 4″ wide foil 0.010″ thick with peak magnetic saturation of 21400 G, and maximum permeability of 4000, and may be tin plated for excellent corrosion resistance and better conductivity. MAGNETSHIELD™ typically reduces fields up to a factor of 2 or 3 depending on size/shape of the shield. In some embodiments, for example to increase shielding to under 10 G permeability, the present invention provides two or more layers or laminates of shielding. In further embodiments, the layer with strongest attenuation is provided nearest the magnetic field source. In particular embodiments, a second layer comprises a foil, for example, MAGNET SHIELDING FOIL™ (Less EMF Inc.). In other embodiments, the present invention provides one or more inter-layer spacers, for example ⅛ inch thick spacers. In certain embodiments, multiple layers of peak saturation alloys are provided for enhanced attenuation in a single shield combining, for example, HyMu “80”® (“MAGNETSHIELD™”) with JOINT-SHIELD™, MAG-STOP™ Plate, MAGNET SHIELDING FOIL™ and/or Metlas™. In preferred embodiments, the size, shape, and position of the magnetic shield is configured for optimal performance in a particular application. The size of the magnetic shield is determined based on the manufacturer's guidelines for the sensitive device, and determining the recommended safe distance for objects with magnets that produce peak gauss measurements to be from the device. These guidelines are also used to obtain an acceptable gauss measurement that would not alter the settings of a medical device. Once that distance is determined, a medical device is measured and the distance determined is used to create a radius around the device. The magnetic shield is then configured to be that size. In general, larger shields dimensions are superior to smaller dimensions, and proximity of the shield to a source of a magnetic field attenuates field strength. In some embodiments, magnetic shields of the present invention are provided parallel to the magnetic field lines rather than perpendicular for greater field attenuation. In other embodiments, magnetic shields of the present invention attenuate magnetic or electromagnetic field strength to under 1000 G, under 500 G, under 200 G, under 100 G, under 50 G, under 20 G, under 10 G or under 5 G.

In some embodiments, the present invention provides magnetic shields comprising GIRON™ Magnetic Shielding Film (Less EMF Inc.). GIRON™ does not contain nickel, is suitable for peak field strength applications requiring peak saturation and good permeability, and for applications in which users may experience nickel allergy. GIRON™ is tolerant to bending or shaping without losing shielding properties. Provided as a woven, laminated material, GIRON™ may be fashioned with snips or sheet metal tools, and may be used either flat or molded into shapes as desired. In preferred embodiments, magnetic shields that comprise GIRON™ are coated with Plasti Dip®, injection molding, plastic or rubber to cover sharp edges.

In some embodiments, the present invention provides magnetic shields comprising of one or both of JOINT-SHIELD™ and MAG-STOP™ Plates (Magnetic Shield Co.), (also known as “MUMETAL®”). JOINT-SHIELD™ is a 0.010″ thick, hydrogen-annealed magnetic shielding alloy with adhesive backing (rated 0-200° F.) on one side, and may be cut with a heavy scissors. JOINT-SHIELD™ is highly corrosion resistant because of its high nickel content.

In some embodiments, magnetic shields of the present invention are selected for an intended application based on specific properties of the shielding material including, for example, field attenuating capacity, pliability, environmental safety and bio-compatibility, user tolerance, concealability, dimensions of intended protection, stability, cost, corrosion resistance, ease of care (e.g., cleaning and washability), and ease of fabrication.

### V. Magnetic Shield Fabrication

In some embodiments, compositions, methods, kits and systems of the present invention magnetic shields of the present invention are provided in diverse shapes and configurations to shield devices sensitive to the detrimental effects of magnetic fields emitted by portable and ambient sources. In other embodiments, magnetic shields of the present invention may be provided in any desired shape. In certain embodiments, magnetic shields are provided in a diversity of standardized and customized shapes and sizes with smooth edges and corners to prevent injury to users and bystanders. Some of the magnetic shields will be in customized shapes and others will be standard circles. In experiments conducted in the development of the present invention, it was discovered that tin snips used for custom cuts lack precision to make exact detailed cuts. Using tin snips, it is also required to trace the design on the alloy before cutting. It was further discovered that tin snips create a bend on the edge of the alloy from the pressure of the cut, with start and stop marks that prevent a smooth edge. In experiments conducted in the development of the present invention, it was also discovered that stained-glass window glass design and shape cutters may be used to score detailed cuts into magnetic shield alloy sheeting, and that thinner grades of the alloy are able to be cut using this method, particularly in the fabrication of shields that require precise and custom angles and designs compared to simple circles, rectangles, and squares and other geometric shapes. In some embodiments, a combined process in which magnetic shield alloys are scored with stained-glass window glass cutters, and then cut with the tin snips, is preferred for thicker shields. In other embodiments, a Glastar™ circle strip cutter or Fletcher™ lens cutter is used to score diverse angles and designs with smooth edges into the magnetic shields of the present invention. In particularly preferred embodiments, a compass Style suction cup 6 Turrets Glass Circle Cutter. The Circle Cutter provides a suction cup to hold the center while a cutter head scribes a circle to fabricate shapes without breakage. In other embodiments of the present invention, a CNC router is used to cut shapes into magnetic shield alloys using a single flute cutter bit or a “0” flute cutter using a proper bit 20,000 to 30,000 rpm to assure the quality of the cut. Magnetic shields fabricated with a CNC router often comprise sharp edges and must be smoothed in a subsequent step. In some embodiments, magnetic shields of the present invention are fabricated with a water jet cutter, a laser with metal cutting option, a punch press with a custom die pattern, or a hand press and die.

In preferred embodiments, a magnetic shield is provided as a circle. The center of the circle is placed at the center of the sensitive device, or at the center of the magnetic field emitting source. This morphology and application assures an even coverage of the magnetic field around the sensitive device or emitting source, also avoids sharp edges and corners. In some embodiments, when concern for soft edges is not as peak, a square with its corners removed with a corner rounder or other cutting method may also be used. A corner-less square reduces alloy wastage, and limits the amount of alloy to be fabricated. In further embodiments, a magnetic alloy shield of the present invention may be provided in a customized shape to resemble the shape of the device it is shielding.

In some embodiments, magnetic shields of the present invention in use are permanently or reversibly folded, pleated, corrugated, or ridged. In other embodiments, layers of superimposed magnetic shield alloys are configured geometric shapes that vary between one another in length, width, thickness and shape. Magnetic shields of the present invention may be provided in a diversity of geometric shapes, widths, thicknesses and lengths.

### VI. Magnetic Shield Coatings and Coverings

In some embodiments, compositions, methods, kits and systems of the magnetic shields of the present invention provided to shield devices sensitive to the detrimental effects of magnetic fields emitted by portable and ambient sources are provided with coatings and coverings. In the course of development of the present invention, it was discovered that the edges and corners of peak saturation alloy magnetic shields may be thin and sharp depending on the method of fabrication. In some embodiments, the magnetic shields of the present invention are left alone with children away from the supervision of adults. In the course of development of the present invention, possible allergies to materials used in the shield, exposure to collateral materials including plastics, environmental impacts of the magnetic shields, consequences of body surface and skin contact, and wash ability of the magnetic shield for re-use without damage to the alloy have been identified. Accordingly, in certain embodiments, the present invention provides coatings and coverings to enhance the benefits of the magnetic shields. In addition coatings and coverings protect the magnetic shield from corrosion and loss of magnetic field shielding attenuation, without loss of its protection of sensitive devices.

In some embodiments, magnetic shields of the present invention are covered with a laminator using polyester film and an extruded heat seal adhesive. Thicker grades of 10 mil may add more protection. For example, a typical 10 mil thick film is constructed of 4/6 (film 4 mils thick and adhesive 6 mils thick). However, in some embodiments, 10 mil thick material may be constructed of 2/8 (8 mils adhesive) material or 7/3 (3 mils adhesive). The ideal laminating temperature varies with the laminate thickness. (Table 1.)

TABLE 1

| Thickness | Temp (F.) |
|---|---|
| (one side) | min/max |
| 5 mil thick | 225/240 |
| 7 mil thick | 240/250 |
| 10 mil thick | 250260 |

In some embodiments, magnetic shields of the present invention are covered with a strong, adhesive, waterproof, tape including, for example, GORILLA TAPE™, HURRICANE TAPE™, and Tenacious Tape™ by Gear Aid™. Tapes and shields are tested to determine wash ability, and dry ability in a household dryer cycle. In certain embodiments, a sheet of peak saturation alloy is provided with tape covering the edges of the shield. Material selection and thickness may vary depending on the level of radiation being shielded. In other embodiments, the magnetic shield is covered with flexible vinyl polyethylene or polypropylene-vinyl. In certain embodiments, two layers of peak quality vinyl are sealed around an alloy disc to create a sturdy cover. In other embodiments, polyethylene covers are provided from a solid sheet of polyethylene plastic with flexibility dependent on the gauge used to construct them. Polyethylene covers may be fabricated from a thin polyethylene such as 0.023 gauge to produce a very lightweight and flexible binder, or the polyethylene material may be a thicker gauge such as 0.075 to create a rigid cover. Common gauges (thickness) include 0.023, 0.035, 0.055, 0.075 and 0.110 gauge. Polyethylene covers are durable and able to withstand very cold and very hot temperatures, making them an ideal choice for shields that will exposed to extreme conditions. Polyethylene covers are also stain resistant and easy to clean, and are suitable for exposure to elements and other circumstances in which a magnetic shield may be subject to harsh climates, conditions and handling. Polyethylene covers are able to withstand being dropped, tossed and handled roughly, and may be screen printed in 1, 2, 3 or 4+ colors

In some embodiments, magnetic shields of the present invention provide covered alloy discs that are applied to magnetic field emitting sources with industrial strength VELCRO®, and high strength Super Glue or comparable strong adhesive. In certain embodiments, a magnetic shield is provided in a pocket with a zipper or other type of reversible closure that allows the shield to be removed before washing and drying. In other embodiments, magnetic shield seams are sealed and waterproofed for use in aqueous environments.

In some embodiments, magnetic shields of the present invention are provided with a covering of soft, waterproof material that may be placed against the skin and is, for example, easily cleaned, hypoallergenic, waterproof, antimicrobial and anti-bacterial. In certain embodiments the covering comprises Nano-pore micro laminated synthetic medical grade material that is 100% waterproof, washable, stain resistant, and anti-bacterial. In other embodiments, the present invention provides waterproof bamboo rayon BuBuBiBi™ nursing pads (70% Oeko-Tex® certified bamboo rayon, 28% OCIA certified organic cotton, 2% polyester.) with absorbent layers of natural fabrics surged together to form a soft, reliable, washable nursing pad. In still further embodiments, the present invention comprises natural or synthetic fabrics coated with waterproofing material, for example, rubber, polyvinyl chloride (PVC), polyurethane (PU), silicone elastomer, fluoropolymers, 10,000, Omni-Tech®, Event, PacLite®, Pro-Shell 2 or 3 Layer, 3-Layer, MemBrain®, PreCip Plus®, Conduit and Tyvek®. In still further embodiments, the covering is disposable.

In some embodiments, magnetic shield coverings of the present invention provide fabrics and materials that are safe and visually and tactilely pleasing for the user. When a fabric choice is given, softer and visually pleasing materials are provided. Fabric choice is also determined by applications in which the fabric can or cannot be removed from the shield. In some embodiments, an antimicrobial shield coating, for example Aegis™, is provided. In some embodiments, sew on patches are applied to the shield to make it more visually appealing, for example, a child's favorite cartoon character or an adult's favorite sports team. As used herein, hot and cold gel pack covers, heating pad covers, micro plush materials, polyester fleece, silk, linen, medical grade fabrics intended to reduce infections and aid in healing, such as X-STATIC® fabric, and bamboo are all considered fabrics. Fabric coverings of the present invention may comprise one or more of cotton, linen, wool, silk bamboo, Lyocell or Tencel™, Modal, Viscose, acetate and synthetic fabrics. In some embodiments, magnetic shield fabric coverings are selected based on one or more characteristics comprising natural vs. man-made, environmental impact, durability, ability to wrinkle, hygroscopy, thermal capacity, dust absorption, shrinkage, breathability and antimicrobial quality.

In some embodiments, magnetic shield coverings and coatings of the present invention provide low nickel and latex allergenicity. In certain embodiments, coatings and coverings comprise one or more plastics including, for example, polyethylene terephthalate (PET or PETE), peak density polyethylene (HDPE), polyvinyl chloride (V or PVC), low-density polyethylene (LDPE), polypropylene (PP), polystyrene (PS), polycarbonate, molded natural rubber polyisoprene (C₅H₈), injection molded polypropylene (PP) plastic, epoxy resins, polyproplylene coploymer, or other plastic. In preferred embodiments, magnetic shield coatings of the present invention comprise Plasti Dip®. In particularly preferred embodiments, magnetic shields coated in Plasti Dip® are covered in a second layer of fabric, including, for example, bamboo rayon. Plasti Dip® is a multi-purpose specialty rubber coating that is applied by dipping, brushing, or spraying. Plasti Dip® protects against moisture, abrasion, corrosion, acids, skidding, and slipping. Plasti Dip® air dries to a rubbery, easy-grip finish and provides a comfortable, controlled grip, does not become brittle or crack in extreme weather conditions (−30° F. to 200° F.), remains flexible and stretchy over time, and is provided in a diversity of colors and tints. Plasti Dip® contains no heavy metals, PVC or other vinyl resins, is resistance to acids, alkaline, and most common household chemicals, with limited resistance to petroleum based products, and may be applied in multiple layers. In some embodiments, Plasti Dip® is used with surface enhancers, metalizers, pearlizers, glossifiers, and primers for stronger and more permanent bonding to metal and plastic surfaces.

### VII. Magnetic Shields and Garments

In some embodiments, compositions, methods, kits and systems of the present invention used to shield devices sensitive to the detrimental effects of magnetic fields emitted by portable and ambient sources are provided in one or more appliances and garments. In certain embodiments, the magnetic shield is worn attached to clothing, worn attached to a neck pouch or lanyard, worn secured to the body using a tight fitting wrap, attached to the body with wraps, bandages or adhesives, or divers other ways of attaching the magnetic shield to keep it in the proper position. In some embodiments, magnetic shields of the present invention are placed in a pocket, purse, static bag, security sleeve, wallet, gloves, mittens, swaddle strap, or stored in other ways to be easily transported as a stand-alone device that can be conveniently utilized as needed. In other embodiments, magnetic shields of the present invention are provided in a waterproof pouch or container comprising GoreTex™ or other waterproof material. In particular embodiments, magnetic shields for use over the lower back, waist or abdomen provide a polyester, Lycra® and/or Spandex® belt with pockets to secure a shield in place including, for example, The FlipBelt®. In other embodiments, soft heart rate monitor straps, for example, by Garmin® and Polar®, are provided to affix a magnetic shield in place over the upper torso, chest or back and to avoid shifting with movement and wear. In further embodiments, a magnetic shield of the present invention is directly attached to a strap with a removable VELCRO® or snap attachment, or permanently attached with a bolt, clamp or a heavy duty water-resistant adhesive.

In certain embodiments, magnetic shields of the present invention are attached to, or placed into, an accessory worn around the neck, such as a lanyard, ID badge or eyeglass holder necklace, or travel/neck pouch. In further embodiments, magnetic shields of the present invention are attached to a retractable clip on cord or lanyard, similar to those used with name badges. In certain embodiments, magnetic shields of the present invention comprise a waterproof neck pouch such as those made by DRYPAK® and the like.

In some embodiments, magnetic shields of the present invention are placed into a pocket on an article of clothing, or are attached to clothing using VELCRO® including, for example, bra pockets and temporary sticky clothing pockets called Pocksie™. For example, Clever Travel Companion™ makes shirts and other travel gear with hidden pockets with and without a zipper closure. In some embodiments, magnetic shields of the present invention are applied to a compression-type shirt or through a bra strap as an anchor, to keep the magnetic shield in the proper position, using a broach, secure pin, snap or button. In further embodiments, magnetic shields of the present invention use suspenders, bandage wraps, straps, and holster belts to securely wear the shield, and to minimize shifting of the shield while it is worn. In some embodiments, magnetic shields of the present invention comprise waterproof garment tape called Flash Tape™ used to hold the shield in place. In still further embodiments, a cotton elastic bandage with a VELCRO® closure is used to apply the magnetic shield and keep it in place. In particular embodiments, snappers are attached to bra straps or suspenders to properly position and hold the magnetic shield in place.

In some embodiments of the present invention, adult and child compression clothing is used to hold the magnetic shield in place in addition to using a pocket or VELCRO® attachment on the article of clothing. In other embodiments, Spanx®, PowerLayer™, Under Armour®, Genie™ and Ahh Bra™, and SPIO™ brands are provided as shirts, pants, bras, vests, hats and the like. In certain embodiments, magnetic shields of the present invention to be placed along the torso including the lower back, waist, or abdomen comprise bands, straps, belts, abdominal compressive garments, postpartum girdles, and the like configured to fit snugly and to not shift with wear. In some embodiments, magnetic shields of the present invention are provided in appliances and garments that can be ironed. In some embodiments, magnetic shields of the present invention are attached to a user's head with a headband, adhesive, bandage, or hat with VELCRO®, an adhesive, a snap, a button, sewing, a pocket, or a hat with a strap, a cinch, or a tie to adjust the fit. In some embodiments, magnetic shields of the present invention comprise a waterproof, breathable headband configured to remain in place. In certain embodiments, the headband comprises a pocket, for example, a BANDI™ headband. In this fashion, the magnetic shield is secured in the proper position and not easily removed. In certain embodiments, THUDGUARD™, No-Shock Helmet™, and SoftTop™ children's hats are used, for example, as soft protective children's headwear with straps that adjustable to ensure a secure compression-like fit to eliminate shifting of the hat and magnetic shield, as are also available in hard hats and helmets. In preferred embodiments, magnetic shields of the present invention comprise shock absorbent materials to blunt impact to a sensitive device or magnetic field source. In some embodiments, hats are lined with loop strips that the hook strips on the magnetic shield may be attached to. Optionally, the magnetic shield may cover the entire inside of the hat, or just in a certain area. Additional styles of hats and headbands may also be used without departing from the invention. It would also be possible to create a pocket in clothing items for the magnetic shield to temporarily or permanently attach the magnetic shield to a hat or other article of clothing. In further embodiments, a hat is tight fitting, and/or has an adjustable strap, to minimize shifting of the magnetic shield during use. In some embodiments, magnetic shields of the present invention are provided in surfer's hats that are waterproof washable and have a secure strap including, for example, FCS and Quicksilver™ hats. In some embodiments, a beanie type skull cap made to wear under bike helmets (PACE™ Sportswear) is provided with a magnetic shield of the present invention with an adjustable cord that provides an adjustable, compression fit. In some embodiments, magnetic shields of the present invention are applied directly to the user's head using methods described below, and then covering the magnetic shield is coved with a hat to secure it in place. In certain embodiments, magnetic shields of the present invention are provided in headbands used in soccer and rugby that provide impact protection without having a crash-type helmet. In some embodiments, foam used in bicycle and ski helmets is add for extra protection element to the magnetic shield that may be molded to provide a cup-like fit around the sensitive device. In some embodiments, the magnetic shield is directly attached to a headband, a bicycle racing or skiing type hat liner, a surfing hat, or a skull or scrub hat.

In some embodiments, magnetic shields of the present invention are covered or coated in a non-skin irritating material and applied to the body surface using 3M™ Tegaderm Film, 3M™ Nexcare, skin tapes and adhesives, elastic sports tapes such as Kinesiology Therapeutic Tape™, KT™ tape, in cotton and synthetic varieties, Smith & Nephew® Skin-Prep Dressings, Smith & Nephew® OpSite Flexifix Transparent Film Roll, SKIN TAC™ liquid adhesive, Smith & Nephew® Uni-Solve Adhesive Remover Wipes, or other adhesive films or bandages. In certain embodiments, the magnetic shield is attached with the alloy protected in a hypoallergenic, inert coating. In some embodiments, the magnetic shield is coated in a protective coating and covered with a bandage, or other non-irritating material to protect the skin from direct contact. In some embodiments, magnetic shields of the present invention are coated and covered in sterile coatings and coverings for use in sterile environments. In certain embodiments, magnetic shields are cushioned for comfort during wearing. In some embodiments, magnetic shield cushions enhance magnetic field attenuation by assuring physical separation between a sensitive device and a field source.

In other embodiments, magnetic shields of the present invention are provided in neoprene coverings for use in contact with a body surface. Neoprene™ has long been worn against the skin in, for example, wetsuits, and gloves. Neoprene™ is stable, maintains flexibility over a wide temperature range, resists degradation, and is inert making it well suited for corrosion-resistant coatings, adhesives, and padding with a snug fit. In other embodiments, magnetic shield coverings comprise Neogreene™, a water-based synthetic with no toxic solvents in its synthesis. In some embodiments, the magnetic shields of the present invention are provided in a Neoprene™ covering used, for example, to protect an external insulin pump from magnetic field emitting sources. In certain embodiments, the magnetic shield is sewn into the case. In other embodiments, the magnetic shield is attached with VELCRO® to be removable. In preferred embodiments, the shield is provided with a coating, for example, Plasti Dip® or similar coating. In further embodiments, magnetic shield side panels are added to the inside of the pouch to protect the sides of the pouch and/or with a top panel as preferred.

In some embodiments, magnetic shields, coatings and coverings of the present invention are fabricated with 3D printing. In other embodiments, magnetic shields may be removably attached and detached to and from a suitable surface, for example to corresponding loop strips that are sewn or otherwise attached to an article of clothing like a hat, shirt, lanyard, cord, elastic band, or strap including a bra strap. In other embodiments, the magnetic shields may be removed and carried independently in, for example, a purse or travel bag. In some embodiments, a purse, travel bag or other container comprises a magnetic shield to shield a removable sensitive device. This allows the magnetic shield to be used in situations when a person may be around devices that are not shielded. In further embodiments, magnetic shields of the present invention are provided with markings including, for example, branding, trademarks, team names and the like. In some embodiments of the present invention, laminated magnetic shields are placed in a waterproof electromagnetic and/or radio field shielding or static shielding bag similar, for example, to a Faraday Bag. In some embodiments, a bag comprises a military grade sealed and waterproof protectant similar in weight and size to a household Ziploc® bag to attenuate RF and EMF interference. A RF jammer faraday type pouch, a black hole pouch, a CTF3™ (cuben fiber) pouch, a LokSak® ShieldSak™, a Nemo EmFx-47, or a hide cell phone privacy bag. In certain embodiments, for example to protect cochlear implants, the present invention comprises a layer of a static blocking shield. In some embodiments, the present invention provides a magnet shield pouch a static guard to store and carry a cochlear implant processor during, for example, airline travel with conveyer belts, low humidity environments, and exposure to security x-rays. In further embodiments, static blocking components of the present invention comprise ALL-SPEC™ static shielding bag, a Hard Drive Anti-static Cushioned Loc-top Bubble Bag, or an IO Crest™ IDE/SATA HDD Storage Box (Extra Packaging Inc.). In still further embodiments, magnetic shields of the present invention comprise anti-static mil spec packaging, metalized static shielding bags, polyethylene anti-static bags, anti-statics sheet protectors, static shielding cushioned bags, static shielding zippered bags, anti-rust zippered poly bags, rubber sleeves rubber layers, hard rubber, nickel, copper, brass, polyester, Saran Wrap®, polyurethane, polypropylene, vinyl, silicon, and Teflon®.

In some embodiments, compositions, methods, kits and systems of the present invention used to shield devices sensitive to the detrimental effects of magnetic fields emitted by portable and ambient sources, magnetic shields are provided in direct contact with a device to be shielded. In some embodiments, a magnetic shield is provided external to a case or housing of a sensitive device. In other embodiments, a magnetic shield is provided internal to a case or housing of a sensitive device. In certain embodiments, a sensitive device is a health care device. In further embodiments, a sensitive health care device is an implantable device. In still further embodiments, a sensitive health care device is a wearable device.

### VIII. Magnetic Shield Appliances

In some embodiments of the present invention, magnetic shields are applied directly to a magnetic field emitting source. When applying a magnetic shield to a magnetic field emitting source, a user first determines the location of the magnets and area of the magnetic field in the source using a gaussmeter or magnetometer, taking care to note anywhere the gauss level is above a safe level. Second, a magnetic shield is applied to the device. Finally, best practice is to measure the magnitude of magnetic field attenuation of the device after application of the magnetic shield to assure that the device is safe to use. In certain embodiments, the magnetic shield is attached to the source with a reversible or permanent adhesive. In other embodiments, a VELCRO® or industrial strength VELCRO® patch is attached to a source, and the magnetic shield is removably attached to the VELCRO® patch. Magnetic shields may be applied to any device emitting magnetic fields without departing from the invention. Magnetic shields may be applied anywhere on a device, and may be adjusted to accommodate different sizes and shapes of cases and electronic device magnetic field sources. In further embodiments, magnetic shields of the present invention may be applied within or external to the case of a magnetic field emitting source.

### IX. Magnetic Field Sensors

In some embodiments, compositions, methods, kits and systems of the present invention provide a magnetic field and/or electromagnetic interference (EMI) sensor and alert to notify a user of the presence of a magnetic or electromagnetic field source in proximity to a magnetic shield. In certain embodiments, the sensor and alert comprise a reed switch, a micro-miniature reed switch, or a Hall Effect sensor. In other embodiments, an alert is an acoustic or visual alert. In further embodiments, a reed switch is operably connected to the positive terminal of a battery that is operably connected to a positive lead of a light emitting diode (LED) or audio alarm, and a negative lead of an LED or audio alarm is connected to a negative terminal of a battery. In particular embodiments, a reed switch is hermetically sealed, capable of several hundred million switching operations with high reliability, and little or no power consumption. In preferred embodiments, magnetic field sensors and alerts of the present invention provide alert tones, series of tones, “all clear” tones, “low urgency” tones (for example intermittent “On/Off” tones), and “high urgency” tones (for example, dual high tones). In other embodiments, a continuous tone indicates continuous exposure to a magnetic field.

### X. Magnetic Shields for Radio Frequency Interference (RFI)

In some embodiments, compositions, methods, kits and systems of the present invention provide magnetic shields from electromagnetic interference (EMI) in the radio frequency spectrum i.e., radio frequency interference (RFI). RFI is the disruption of operation of an electronic device when it is in the vicinity of an electromagnetic field (EM field) in the radio frequency (RF) spectrum that is caused by another electronic device. RFI may cause mechanical failure, reprogramming, alarm resetting, temporary damage or permanent damage to components and circuits of an electronic device. EMI and RFI may arise from a diversity of sources including, for example, personal computers, cathode ray tubes, wireless transmitters, RF scanning devices, near field communication devices, unauthorized intentional or unintentional reprogramming devices using RF signals (e.g., “hacking”), antennas, radios, walkie talkies, citizens band (CB) radio, uninterrupted power sources (UPS), cellular phones, home wireless electronics, cordless phones, headphones, OnStar™ Technology units, security badge scanners, routers, smartphones, Bluetooth®, electronic measurement devices, tablets, wireless controllers, video game consoles, digital music players, remote keyless entry devices, remote car starters, smart meters, instruments for radio frequency ablation, electro-acupuncture, MRI and CAT scan, electrolysis, electro-cautery, external defibrillators and cardio-verters, lithotripters, radiotherapy, ultrasound, stereotaxis, transcutaneous electrical nerve stimulation (TENS), neuro-muscular electrical stimulation, digital hearing aids, transurethral needle ablation, diathermy (high frequency, short wave, and microwave), dental instruments, small and large motors (e.g., chainsaws, snow blowers, lawn mowers, etc.), home-care appliances, charging bases, magnetic therapy devices, radio-controlled devices, electronic exercise equipment, automotive electronics, electrical fences, transformers, metal detectors, induction cooktop stoves, body fat measuring devices, massagers, welding equipment, battery powered cordless tools, games comprising magnets, slot machines, security systems, theft detection systems, radiation therapy units, and the like. In some embodiments of the present invention, shielding is provided from EMI and RFI sources comprising an electronic article surveillance system at, for example, very low frequency (VLF=3 kHz-30 kHz), low frequency (LF=30 kHz-300 kHz), intermediate frequency (MF=300 kHz-3 MHz), and high frequency (HF 3 MHz-30 MHz). For example, certain acoustomagnetic systems use a transmitter that transmits a signal at 58 kHz in pulses. Swept-RF systems use a transmitter that transmits an RF signal between 7.4 and 8.8 MHz. Other electromagnetic systems use a transmitter that creates a low frequency (e.g., between 70 Hz and 1 kHz) electromagnetic field between two pedestals at exit areas.

A diversity of devices are sensitive to EMI and RFI including, for example, cordless telephones, computers, and health care devices, for example, neurologic devices (e.g., VPS, VNS, nervous system stimulators), cardiac devices (e.g., pacemakers, ICDs, VADs), infusion pump devices and the like that may fail to operate properly in the presence of strong RF fields. For example, pacemakers and ICDs incorporate cardiac sensing capabilities in order to sense electrophysiological signals that may make these devices more sensitive to external low frequency RF signals. Due to their sensing capabilities, pacemakers and ICDs may be more likely to misinterpret external RF emissions as an electrophysiological signal.

In some embodiments, a device sensitive to RFI comprises a deep brain stimulation (DBS) system comprising a magnetic control device or “programmer”. Persons using a programmer to communicate with a DBS are counseled to avoid EMI sources to prevent deactivation or malfunctions. In certain embodiments, the present invention provides magnetic and RFI shields to DBS devices and programmers, and to magnetic field and RFI sources that may interfere with or reprogram a DBS system.

In some embodiments, a device sensitive to RFI comprises a spinal cord stimulation (SCS) system. SCS is a pain relief modality that delivers a low-voltage electrical current continuously to the spinal cord to block the sensation of pain. SCS systems may provide a magnet for operation of stimulator control device. The magnet of the stimulator control device may damage sensitive items such as watches, or erase information on items with magnetic strips including credit cards, video or audiocassettes, computer readable media and the like. In some embodiments, the present invention provides a storage option for a SCS system control magnet. In other embodiments, magnetic shields of the preset invention prevent interference and reprogramming from magnetic field and RFI sources in a user's environment. In certain embodiments, the present invention provides a band that fits around the waist that houses a magnetic shield. In other embodiments, a magnetic shield is attached to the band using VELCRO®, snaps, sewn in, placed in an attached pocket or pouch, or other method of attachment is employed. Anti-theft devices in retail stores, electronic doors or metal detectors may increase SCS stimulation or cause an electrical shock if the SCS system is activated. Users are counseled to de-activate the SCS system before knowingly passing through anti-theft devices. In certain configurations the SCS system uses a receiver to transmit mild electrical impulses to the spinal cord using RF signals passed through the skin from a transmitter worn externally on a belt. In such an SCS system a replaceable taped patch with an antenna wire connected to the transmitter is placed on the skin directly over the site of the implanted receiver. SCS systems of this and related designs may be sensitive to ambient RFI from, for example, radio frequency identification (RFID) emitters, diathermy, ablation devices, cardiac and other neurologic EMI emitting devices, ultrasound and the like resulting in system damage, inhibition of output operational changes to the SCS, or unexpected changes in stimulation. In turn, unshielded use of the SCS may interfere with the performance of other EMI sensitive devices.

In some embodiments, the present invention provides magnetic and electromagnetic shields for RFID tags and readers. RFID readers have one or more antennas that emit radio waves and receive signals back from an RFID tag. RFID tags that use radio waves to communicate their identity and other information to proximate readers may be passive or active. Passive RFID tags are powered by the reader and do not have a battery whereas active RFID tags are powered by batteries. RFID tags may store a range of information from a single serial number to several pages of data. Readers may be mobile and carried by hand, or they may be mounted, for example, on a post, overhead or in architecture. RFID systems employ radio waves at different frequencies to transfer data regarding, for example, purchasing, inventory control, equipment and sample tracking, personnel tracking, monitoring, information control, and data management systems. In some embodiments, RFID transmitters are a source for EMI with the potential to damage or degrade the performance of sensitive electronic devices including, for example, neurologic, cardiac, infusion pump and other devices.

In some embodiments, the present invention provides shielding to prevent unwanted EMI in the RF spectrum from entering or leaving sensitive electronic devices that interfere with, or are interfered by, RFID tags and emitters. Carrier frequencies and antenna type distinguish 134 kHz frequencies of RFID emitters and emitters of higher frequencies. Close to the emitter antennas, also known as the “near field” region, low frequency antennas emit primarily magnetic fields. This is the case for 134 kHz RFID emitters. Emitters causing EMI may have magnetic field intensities at or above 162 A/m at 2.5 cm away from antenna. In the near field region, the strength of a magnetic field decreases with the cube of a distance so that the identical effects of RFID emitters do not occur at greater distances of separation. In particular embodiments, RFI blocking materials are provided in addition to magnetic shields of the present invention. In certain embodiments, magnetic shields and RFI-blocking materials comprise Tyvek® made of high-density polyethylene fibers, metallic foil, and/or signal shields. In some embodiments, RFI blocking materials are applied directly to the alloy component of a magnetic shield, are added as an additional layer to a magnetic shield, are worn separately from a magnetic shield, or are provided as a component of a magnetic shield cover. In certain embodiments, the present invention further comprises electronic RF filtration compositions and systems. In particular embodiments, the present invention provides magnetic and electromagnetic shields to prevent wireless data theft, for example, theft of financial or health care data transmitted by an RFID system. In other embodiments, computer readable media (e.g., credit card or electronic health record data on transportable media) are transported in a carrier comprising a magnetic and/or electromagnetic shield of the present invention to prevent access to data by an unauthorized RFID reader. In particular embodiments, the present invention provides a wallet, purse or packet comprising a built-in or removable RFID blocker.

In some embodiments, the present invention provides compositions, methods, kits and systems configured to interfere with or “jam” EMI and RFI to prevent eavesdropping, hacking and wireless attack of a sensitive device. In certain embodiments, the present invention comprises jamming coils, antennas, and RFID reflecting and jamming chips. In other embodiments, communication between a sensitive device and peripheral device is provided by a jamming transmitter small enough to be worn as a watch or necklace configured to access a sensitive device and send encrypted instructions to a transmitter or remote terminal configured to decode encryption and relay instructions to the sensitive device to assure approved reprogramming and prevent unauthorized re-programming.

In some embodiments, magnetic shields and electromagnetic interference shields of the present invention provide improved operational security of sensitive devices. For example, third parties may unintentionally or intentionally use RF signals to deplete batteries of sensitive devices, or to interfere with essential functions of a sensitive device by deactivation, inappropriate activation, reprogramming of sensor thresholds, and the like. Even with contemporary electronic safeguards to hardware and software, an adversary may bypasses a sensitive device programmer using RFI. In other embodiments, magnetic shields and electromagnetic interference shields of the present invention provide improved security and privacy of data wirelessly transmitted to and from sensitive devices and receivers including for example, personal identification data, health care data (e.g., telemetry data, personal health information data), and financial data. In certain embodiments, the present invention protects sensitive devices from communication with unauthenticated devices and unauthorized parties with in-range radio-communicators or external programmers. In some embodiments of the present invention, the operational security, functional integrity, and data security of sensitive devices is provided by zero-power (e.g., drawing no power from a primary battery, and driven by RF energy from an external source (WISPer, which is a WISP UHF RFID® tag augmented with a piezo-element)) notification to a user that audibly warns a user of security-sensitive events such as unauthorized access of their implanted medical device. In other embodiments, zero-power (i.e., RF energy) authentication provides symmetric cryptographic protocols to authenticate requests from an external device programmer, and to preclude unauthorized access to programmable sensitive devices. In further embodiments, elements of zero-power notification and zero power authentication are combined to allow users to physically sense an acoustic or tactile vibration key exchange. In some embodiments, the present invention provides magnetic shields and electromagnetic shields with RF jamming capacity comprising, for example, a parallax propelle chip, a Wave Bubble 2010b Custom PCB®, or similar RF jamming product.

### EXPERIMENTAL

The following section provides exemplary embodiments of the present invention, and should not be considered to be limiting of its scope with regard to alternative embodiments that are not explicitly described herein.

### Example 1

### Magnetic Shields Alloys

Aims:

Magnets with gauss measurement s from 90 G to 1000 G that are common in household items and toys may unintentionally reprogram sensitive devices that are themselves intentionally reprogrammable with a magnet. In the present experimental example, alloys for use between sensitive devices and magnetic field sources were compared for magnetic field attenuation.

Methods:

Alloy sheeting comprising GIRON™, JOINT-SHIELD™, and 0.01″ and 0.015″ thicknesses of MAGNETSHIELD™ cut into 1″ by 2″ strips to test for attenuation of DVD player magnetic field attenuation, and 1″×3″ strips to test for the iPad®2 magnetic field attenuation. A DC Gaussmeter, model GM-1-HS (AlphaLab Inc.) was used to measure the base gauss measurement s of an Apple iPad®2, and a SYLVANIA® DVD player, model SDVD1030. Locations to be tested on the iPad®2 were selected in accordance with locations noted by a manufacturer of sensitive devices to be able to reprogram a sensitive device and reset a valve. (<http://www.medhelp.org/posts/Chiari-Malformation/FYI-Those-with-Programmable-SHUNTS/show/1661065>) The magnetometer in present use was found to provide measurements of emission very similar to the manufacturer's information, and was further calibrated with a reference magnet of known gauss.

Samples of alloy components of the magnetic shields of the present invention were then applied directly over the imbedded magnets in the iPad®2 and the DVD player. Peak gauss measurements were determined by scanning the tip of the sensor directly over the iPad® and the DVD player to determine the peak gauss emitting locations. Alloy shield samples were then applied directly over the peak gauss measurement sites. The peak gauss emission site was located by passing the magnetometer over the alloy shield. Peak gauss measurements were measured in a ¼″ by ½″ horizontal lane over the previous peak gauss magnet measurement, and the peak gauss measurement was recorded.

Results:

JOINT-SHIELD™ samples were observed to be superior shields for the iPad®2, and to be the least gauss shield for the SYLVANIA® DVD player suggesting that JOINT-SHIELD™ is not a preferred alloy for use as a universal magnet shield component. (Table 2.) JOINT-SHIELD™ may find use in magnetic shields of the present invention as a layering product, or as a shield for a specific magnetic field source. GIRON™ samples were second best for attenuating magnetic fields emitted from the iPad®2, and the best for those emitted by the SYLVANIA® DVD player. GIRON™ was found to be difficult to cut, have sharp edges, and is relatively thick, stiff, and heavy compared to the other products, because it is provided in a weave pattern that must be segregated into solid strips uniform gauss blocking ability. These features limit the applicability of GIRON™ in certain embodiments of the magnetic shields described herein. However, GIRON™ does not contain nickel so it is an option for applications wherein nickel allergies are to be avoided. Although the MAGNETSHIELD™ alloy samples scored 3^{rd} and 4^{th} for the iPad®2, and 2^{nd} and 3^{rd} for SYLVANA® DVD player in magnetic field attenuation, the samples were effective at blocking gauss to a level well below 90. Consistency of gauss blocking performances, flexibility, light weight and thinness, and ease in cutting suggest that MAGNETSHIELD™ in 0.010″ and 0.015″ thicknesses is a suitable options for use as a component of the magnetic shields of the present invention.

TABLE 2

| | | | | | Peak | |
|---|---|---|---|---|---|---|
| | | | | Peak Gauss | Gauss | |
| | | | | Measurement | Measurement | Peak Gauss |
| | Base | | Peak Gauss | with | with | Measurement |
| Household | Level of Peak | Location of | Measurement | MAGNET | MAGNET | with |
| Electronic | Gauss | Peak Gauss | with | SHIELD ™ | SHIELD ™ | JOINT- |
| Type | Measurement | Measurement | GIRON ™ | .010″ | .015″ | SHIELD ™ |
| iPad ® 2 | 346 G | Right front | 2.85 G | 3.44 G | 3.06 G | 1.32 G |
| | | edge, 4¼″ | | | | |
| | | down from | | | | |
| | | top, and ⅛″ | | | | |
| | | in from edge | | | | |
| SYLVANIA ® | 311 G | Directly over | 6.37 G | 13.96 G | 11.67 G | 20.18 G |
| DVD | | speaker on | | | | |
| | | the bottom | | | | |
| | | left of the | | | | |
| | | display | | | | |
| | | screen. | | | | |

Conclusions:

Table 1 shows that MAGNETSHIELD™ 0.010″ and 0.015″ and GIRON™ are effective at attenuating gauss levels of 311 G to 346 G fields to values consistently less than 14 G. Precut MAGNETSHIELD™ strips and shield dimensions are more convenient for fabrication compared to, for example, GIRON™ alloys. Strength of the field source to be attenuated is a further consideration in shield fabrication. JOINT-SHIELD™ became saturated at 311 G and was the superior shield at the 346 G measurement.

### Example 2

### Magnetic Field Sources

Aim:

Magnetic field gauss emissions of common household toy and electronic sources were measured

Methods:

A DC Gaussmeter model GM-1-HS®, and a DC Gaussmeter Model 1-ST®, were calibrated by a 500 G reference test magnet. Each test item was scanned with a gaussmeter sensor tip directly touching the surface of the item. The peak gauss measurements were recorded. The peak gauss measurements were also confirmed by a second observer.

Results:

Common in the household items and environments comprise toy or electronic products with, for example, a speaker or magnet that emits a peak gauss measurement over 90 G. (Table 3.) Electronic devices without speakers such as the iPod Nano® and iPod Shuffle® emit less than 4 G. Stuffed toys intended to stick to, or “kiss”, another toy carried the peak gauss emission measurements. Puzzles and books with speakers were also commonly emitted over 90 G fields. Inter-observer accuracy was found to be to +/−10 gauss or +/−1-2%.

Conclusions:

Toys and electronics in the home that emit magnetic fields with a strength over 90 G are common and may be encountered on a daily basis. Any toy or electronic that makes noise is likely to contain a magnet. Any toy or device that is intended to stick to another surface or toy with a magnet is likely to contain a very strong magnet. Items with thicker plastic or materials on the surface above the speaker components greatly reduce emitted gauss levels, for example, books and puzzles with a on the front may have a plastic covering and measure 60 G, yet the back of the book may not have this additional barrier and measure 151 G.

TABLE 3

| | Peak Gauss | |
|---|---|---|
| Test Item Description | Measurement | Location of Peak Gauss Measurement |
| 3″ THOMAS & FRIENDS ® toy | 347 G | Bottom of front circular magnet |
| train with magnet connectors | | |
| Apple ® Earbuds used for ipad ®, | 238 G | Center of left earbud |
| iPod nano ® (1.89 G), iPod shuffle ® | | |
| (3.48 G), and iPod touch ®. | | |
| Samsung ™ Headset J4 | 58 G | Along silver rim of earbud |
| EHS64AVFWE | | |
| iPod nano ® model A1446 | 1.89 G | Not significant |
| iPod shuffle ® | 3.46 G | Not significant |
| Nintendo ® DS* | 421 G | Inside top cover right speaker |
| Nintendo ® DSI* | 461 G | Inside top cover right speaker |
| Nintendo ® 3DS* | 523 G | Outside top cover left side reverse side of |
| | | inside top left speaker |
| Blueparrot ® hands free bluetooth | 277 G | Speaker |
| Leapster 2 LeapFrog ® | 156 G | Speaker on front right |
| LeapPad2 by LeapFrog ® without | 249 G | Right side edge surface measurement off |
| case | | magnetic pen holder indentation. |
| VTech ™ Dial & Discover Phone | 124 G | Speaker on back top |
| Samsung ™ Galaxy III smart phone | 342 G | Near the speaker on back, top, left of phone |
| Faberware ® refrigerator chip clip | 1261 G | Magnet on back of clip |
| magnet | | |
| Hallmark ® Kissing Bear Ornaments | 2991 G | Surface measurement of nose and mouth area |
| Kissing Simba Lion King-Plush | 1525 G | Surface measurement of nose and mouth area |
| Toy | | |
| ProMAG ™ Neodymium Magnets | 1236 G | Magnet Surface |
| Michael's Craft Store ½″ | | |
| ProMAG ™ Flexible Magnets | 548 G | Magnet Surface |
| Michael's Craft Store ¾″ | | |
| Melissa & Doug ® Sound Puzzle | 94 G | Top Left Corner Speaker Surface |
| Baby Einstein ™ Discover The Day | 151 G | Back bottom left corner opposite of the |
| Lift-A-Flap Sound Book | | location of the speaker on the front |
| iPod Touch ® Gen 4 | 255 G | Front, bottom, left corner |

*Magnetic shield cases of the present invention, and 1″ × 1″ 0.015″ alloy magnet shields attached directly to the surface of the DS product over the peak gauss speaker areas with an optional NERF ™ Armor Case reduces peak gauss measurements to less than 20 G.

### Example 3

### Magnetic Shield Water Corrosion

Aim:

To determine if a magnetic shield alloy of the present invention is resistant to corrosion and loss of shield capacity in a household environment, samples of MAGNETSHIELD™ 0.015″ alloy (Less EMF Inc.) were investigated under 6 conditions. These conditions were used to replicate washing and moisture situations that magnetic shield alloys may be exposed to during typical use in a home environment.

Methods:

Four glass vessels were filled with 8 ounces of tap water from a household well. The alloy was cut into 2′ circles or other geometric shapes and placed into a plastic holder. The plastic holder was placed on the bottom of a cup so that the sample of alloy would remain vertical in the glass for the testing period. Care was taken to not cross contaminate samples. The vessels were placed out of direct sunlight and were examined twice daily for up to 8 days to detect evidence of rust or other corrosion on the samples. Experimental conditions were:

Sample 1—MAGNETSHIELD™ HYMU “80” ® Alloy disc placed in 8 ounces of tap water
Sample 2—MAGNETSHIELD™ HYMU “80” ® Alloy disc placed in 8 ounces of Nestle Pure Life Bottled Purified Water
Sample 3—MAGNETSHIELD™ HYMU “80” ® Alloy disc placed in 8 ounces of tap water with 1 tsp of Palmolive Pure & Clear Dishwashing Liquid (surface scratches were noted on the sample)
Sample 4—MAGNETSHIELD™ HYMU “80” ® Alloy disc placed in 8 ounces of tap water with Tide Free & Gentle Liquid laundry detergent
Sample 5—MAGNETSHIELD™ HYMU “80” ® Alloy disc washed in the pots and pans setting of a dishwasher with Cascade® Complete All-In-One Action Pacs
Sample 6—MAGNETSHIELD™ HYMU “80” ® Alloy disc washed in a washing machine using Gain® Flings 3 in 1 Detergent Pacs on the normal wash setting and dried on the peak heat setting in a standard household drier.

Results:

All samples were re-tested at the conclusion of the experiment to detect a change in magnetic field gauss blocking capacity. No post-exposure gauss blocking capacity decrement was observed. Examination for corrosion revealed is shown in Table 4.

TABLE 4

| | Rust Present | | Details on |
|---|---|---|---|
| | Y for Yes or | Time of rust | Rust |
| Samples | N for No | formation | Formation |
| Sample 1- Tap water | Y | 2 Days | Rust Located |
| | | | around the |
| | | | Edges |
| Sample 2- Purified | N | N/A after 8 days | N/A |
| Water | | | |
| Sample 3- Tap water | Y | 4 days | Rust on |
| and Dish soap | | | Alloy |
| | | | Scratch |
| | | | Marks |
| Sample 4- Tap Water | N | 5 Days | N/A |
| & Laundry Soap | | | |
| Sample 5- Dishwasher | N | 1 Cycle | N/A |
| & Dishwasher Soap | | | |
| Sample 6- Washer, | N | 1 Cycle | N/A |
| Dryer, & Laundry Soap | | | |

Sample 1 showed visual rust around the edges within 2 days.
Sample 2 showed no visual rust after 8 days.
Sample 3 showed visual rust after 4 days on the portion of alloy that had previously been scratched on the edges.
Sample 4 showed no visual rust after 5 days.
Sample 5 showed no visual rust after one dishwashing cycle.
Sample 6 showed no visual rust after one wash cycle with a standard wash machine and one high heat dryer cycle.

Conclusions:

In certain applications, magnetic shields of the present invention may require washing. The tap water and the dish soap exposure of the present experiments demonstrated evidence of rust within 4 days sufficient to warrant an additional protective coating for the magnetic shield alloy. Different results between Samples 3 and 4 may have been caused by differences in the viscosity of laundry soap giving rise to differences in coating the alloy disc to form a barrier against the tap water. Scratches on Sample 3, or variations in exposure time, may also account for the differences in results. Alternatively, differences in the compositions of the laundry detergents may cause differences in the properties of tap water to prevent or enhance rust formation. The magnetic shields of Samples 5 and 6 were washed and dried quickly after exposure to moisture, and no rust was observed in these tests. Accordingly, hand washing magnetic shields of the present invention with purified water, and drying quickly, will be an option to reduce corrosion in some embodiments. Drying a magnetic shield in a clothes dryer caused no visual or functional damage to the alloy.

### Example 4

### Cell Phone and SmartPhone® Magnetic Field Sources

Aim:

To determine the preferred phone, case, and magnetic shield combinations for Smartphones® based on shielded peak gauss measurements, the Samsung® Galaxy SIII model SCH-R53OU, iPhone® 4 model A1332, and iPhone® 5S model A1453 phones were compared to determine peak gauss measurements without a case, and peak gauss measurement s with a case that comprises a built-in screen protector.

Methods:

An unaltered Samsung® Galaxy SIII model SCH-R53OU, iPhone® 4 model A1332, and iPhone® 5S model A1453 phones were all scanned with a DC Gaussmeter Model 1-ST calibrated with a 500 G reference magnet and zeroed. The phones were scanned with the gaussmeter sensor placed directly against the surface of the phone, or the case. The locations of the peak measurements were recorded, and the locations were re-measured with cases installed. Unaltered cases used were: an OtterBox® Defender and a Trident™ Aegis Series Case for the Samsung® Galaxy SIII; an OtterBox® Defender Case for the iPhone 4 model A1332; and an OtterBox® Defender Case and a Body Glove® Shock Suit Case for the iPhone® 5S model A1453. Because gauss measurements on the sides of the phones were low and covered by the cases, these measurements were not recorded. Screen protectors comprised of Sonix Screen™ and InvisibleSHIELD™, and were provided over magnets the touch screen surface of the phone including, for example, such the iPhone® 5S

Results:

Samsung® Galaxy SIII Model SCH-R53OU

The Samsung® Galaxy SIII model SCH-R53OU was tested with an OtterBox® Defender Case and a Trident™ Aegis Series Case. (Table 5.)

TABLE 5

| | Peak Front Gauss | Peak |
|---|---|---|
| Phone and Case | Measurement | Back Gauss Measurement |
| Samsung ® Galaxy | 55 G | 342 G |
| SIII without a case | Location: top front | Location: top right back |
| Samsung ® Galaxy | 36 G | 31 G |
| SIII with OtterBox ® | Location: top front | 144 G inside case cutout |
| Defender Case | | Location: top back |
| Samsung ® Galaxy | 53 G | 39 G surface |
| SIII with Trident | Location: top front | 93 G inside case cutout |
| Aegis Case | | Location: top back |

iPhone® 4 Model A1332

The iPhone® 4 model A1332 was tested with an OtterBox® Defender Case. (Table 6.)

TABLE 6

| Phone and Case | Peak Front Gauss Measurement | Peak Back Gauss Measurement |
|---|---|---|
| iPhone ® 4 without a | 105 G | 41 G |
| case | Location: top, front, center by | Location: top, left, back |
| | speaker slit | 124 G |
| | 59 G | Location: back, bottom, left, |
| | Location: front, bottom, right | corner |
| | corner | |
| iPhone ® 4 with | 18 G surface | 11 G surface |
| OtterBox ® Defender | 100 G inside case cutout | 45 G inside case cutout |
| Case | Location: top front, center by | Location: top, back, left |
| | speaker slit | |
| | 20 G | |
| | 26 G | |
| | Location: bottom, front, right | |
| | corner | |

iPhone® 5S Model AA1453

The IPhone® 5S model A1453 was tested with an OtterBox® Defender Case and a Body Glove™ Shock Suit Case. (Table 7.)

TABLE 7

| | Peak Front Gauss | |
|---|---|---|
| Phone and Case | Measurement | Peak Back Gauss Measurement |
| iPhone ® 5S without | 158 G | 364 G |
| a case | Location: top center front by | Location: top right back |
| | speaker slit | 209 G |
| | 238 G | Location: bottom, left, back |
| | Location: bottom right front | |
| iPhone ® 5S with | 31 G surface and 62 G inside | 41 G |
| OtterBox ® Defender | case cutout. | Location: top back center |
| Case with two layers | Location: top center front | 29 G |
| of screen protectors | 192 G | Location: bottom back |
| | Location: bottom right front | |
| iPhone ® 5S with | 99 G at surface and 133 G | 67 G |
| Body Glove ® | inside case cutout. | Location: top back |
| Shocksuit Case | Location: top center front | 71 G |
| | 170 G | Location: bottom back |
| | Location: bottom right front | |

Conclusions:

Present results demonstrate that certain cell phones and SmartPhone® models are lower in magnetic field emission strengths than others. For example, the iPhone® 4 peak gauss measurements are the lowest at 124 G without a case, and the iPhone® 5S and the Samsung™ Galaxy SIII each measure over 340 G without a case. Moreover, these data reveal that achieving gauss levels below target 5-10 G thresholds suggested by manufacturers of certain sensitive devices (e.g., ICDs) requires modifications comprising layers, heterogeneous alloys, spacers and the like, whereas target 90 G thresholds suggested by manufacturers of other sensitive devices (e.g., ventriculo-pertioneal shunts (VPSs)), or 600 G for other sensitive devices (e.g., insulin pumps) is feasible with less complex and costly configurations, designs and fabrications. Accordingly, magnetic shields of the present invention are in some embodiments fabricated and manufactured to specifications dictated by diverse sensitive devices, diverse magnetic sources, or both. As well, present results show that phone cases differ in their capacity to block magnetic fields emitted by different cell phones and SmartPhones®. In some embodiments of the present invention, magnetic shields may be directly attached to an integrated screen protector with one or more interposed layers to further attenuate magnetic field strength. Each of the tested phones contained regions of over 40 G emission that were often located near speaker and internal magnets within the phone located, for example, under the screen protector, or on the front touch screen portion of the phone. Hence, magnetic shields of the present invention may in certain embodiments be provided with cutouts to enable access to touchscreen features, and to limit the probability that a sensitive programmable device may be placed in proximity to a magnetic source within a case. In further embodiments, a cell phone or SmartPhone® case comprising a magnetic shield of the present invention is provided that is customized to the brand, make and model of the phone. In certain embodiments, a case provides a locking case system to prevent removal by a child, and to reduce shifting. In keeping with these experimental results, in some embodiments, magnetic shield phone cases of the present invention provide a screen protector and waterproofing, and are attached to shield peak emission areas of the phone in combination with a magnetic shield of the present invention.

### Example 5

### Magnetic Field Attenuation

Aim:

The aim of this experimental example was to compare diverse alloys, layers, coatings, coverings, spacing, weights and dimensions of magnetic shields for peak shielding capacity Methods: In Protocol 1, a ProMAG® 282 G, and 545 G flexible magnets purchased at a craft store were used to determine the field attenuating performances of the 0.014″ and 0.015″ HyMu “80”™ and MAGNETSHIELD™ alloys. The magnetic field source was placed on the center of the alloy samples, and a DC magnetometer sensor tip was placed directly on the opposite side of the sample from the magnet. Peak gauss measurements were recorded on the opposite size in a ¾″ diameter circle. In Protocol 2, a ½″ diameter neodymium magnet with a peak gauss of 2353 G was used. A gauss field strength of 2353 G was confirmed by scanning the sensor directly over the front and back flat surfaces of the magnet, and recording the gauss observed. This magnet was chosen for its peak gauss emission, and its widespread commercial availability. A DC Gaussmeter model GM-1-HS®, and a DC Gaussmeter Model 1-ST®, were calibrated by a 500 G reference test magnet with an observed test-re-test reproducibility of 1-2%. The test magnet was placed in the center of each test sample, and the magnetic field attenuation was then measured in the center on the surface opposite to the surface with the magnet. The sensor tip of the magnetometer was placed directly onto the surface and was circulated in a ¾″ diameter circular area to determine the peak gauss measurement. In Protocol 3, diverse thicknesses of HyMu “80”® alloys ranging from foils 0.004″ thick up to 0.04″ HyMu “80”®, HyMu “80”® 0.014″ and MAGNETSHIELD™ 0.015″ were tested, together with other material samples for comparisons. These samples were cut into 4″, 4.5″ and 5″ discs. Plasti Dip® was applied to both sides of a subset of the test alloy samples with a thickness of 0.035″ thicker on average. In some samples 2⅛″ thick Scotch® self-stick rubber pad spacers were applied between two sample material layers. The total additional space created was up to ¼″ thick. In some magnetic shields, VELCRO® and BubuBibi™ bamboo pads on each surface increased the thickness by 0.30″.

Results:

HyMu “80”® 0.014″ thick alloy was observed to block magnetic fields of 282 G or less to under 5 G. (Table 8 and Table 9.) MAGNETSHIELD™ 0.015″ thick alloy was observed to block magnetic fields at higher strengths, for example up to 545 G. Greater diameters were not observed to improve the field attenuating capacities of sample alloy discs. 0.015″ MAGNETSHIELD™ alloy in a 4″ disc was observed to block 98.2% to 98.1% of emitted gauss. MAGNET SHIELDING FOIL™ was observed to attenuate residual 10 G or less. It is very thin, easily cut, and does not add substantial weight.

TABLE 8

| | Peak magnet | HyMu “80” ® | MAGNETSHIELD ™ |
|---|---|---|---|
| Disc width | gauss level | 0.014″ | 0.015″ |
| 4″ | 282 G | 2.24 G | 5.48 G |
| 4″ | 545 G | 174 G | 10 G |

TABLE 9

| | Magnet | | | | |
|---|---|---|---|---|---|
| AlloyWidth | Gauss | 1.5″ | 2″ | 3″ | 4″ |
| .015″ | 282 G magnet | 6.55 G | 5.77 G | 5.74 G | 5.48 G with |
| MAGNETSHIELD ™ | | | | | 1.9% residual G |
| 0.014″ HyMu “80” ® | 282 G magnet | 4.03 G | 3.05 G | 2.37 G | 2.24 G with |
| | | | | | 0.8% residual G |
| 0.015 | 545 G magnet | 15 G | 12 G | 11 G | 10 G with 1.8% |
| MAGNETSHIELD ™ | | | | | residual G |
| 0.014″ HyMu “80” ® | 545 G magnet | 180 G | 178 G | 177 G | 174 G with |
| | | | | | 31.9% residual G |

The weave pattern of GIRON™ was observed to alter magnetic field attenuation. Comparable peak attenuation was observed at specific locations on the GIRON™ alloy, but ¼″ away from a peak location, attenuation may be lower than that observed with 0.014″ and 0.015″ alloys. (Table 9.) GIRON™ is thicker and heavier than the other alloys. Adding a 0.035″ coating of Plasti Dip® to the alloy sample discs was observed to block further attenuate magnetic field emission strength. (Table 10.)

TABLE 10

| Magnetic shield material | Peak Gauss Level |
|---|---|
| Single layer of 0.015″ MAGNETSHIELD ™ in a 4″disc | 1119 G |
| Single layer of 0.015″ MAGNETSHIELD ™ in a 4″disc and coated in | 651 G |
| Plasti Dip ® | |
| Single layer of 0.015″ MAGNETSHIELD ™ in a 4″disc, coated in Plasti | 502 G |
| Dip ®, with a 4″ disc of MAGNET SHIELDING FOIL ™® | |
| 2 layers of 0.015″ MAGNETSHIELD ™ in 4″ discs | 284 G |
| 2 layers of 0.015″ MAGNETSHIELD ™ in 4″ discs and coated in Plasti | 9.3 G |
| Dip ® | |
| 2 layers of 0.015″ MAGNETSHIELD ™ in 4″ discs and coated in Plasti | 6.2 G |
| Dip ®, and a ¼″ spacer in the middle. | |
| 2 layers of 0.015″ MAGNETSHIELD ™ in 4″ discs, coated in Plasti | <1 G |
| Dip ®, a ¼″ spacer in the middle, and one 4″ disc layer of MAGNET | |
| SHIELDING FOIL ™ | |
| 2 4.5″ layers of GIRON ™, uncoated, with a ⅛″ spacer | 5.1 G |
| 2 4.5″ layers of GIRON ™, uncoated, with a ⅛″ spacer, and a 4″ disc | <1 G |
| of MAGNETSHIELDING FOIL ™ | |
| 2 layers of BubuBibi ™ bamboo padding with VELCRO ® 0.035″ thick, | <5 G |
| 1 4″ disc of 0.015″ MAGNETSHIELD ™, and 1 layer of 4″ disc of | |
| MAGNET SHIELDING FOIL ™ | |

Conclusions:

HyMu “80″® 0.014” thickness was observed to attenuate magnetic fields best in lower gauss ranges, for example, a 272 G. The MAGNETSHIELD™ 0.015″ thickness was observed to attenuate magnetic fields best at higher levels, for example, such a 545 G. Increased alloy disc diameters improved field attenuation, but may not have been sufficient to outweigh the extra size and weight of the larger discs in many applications. If, however, small enhancements in attenuation are required without increasing thickness, a larger diameter sample is a useful feature. In some embodiments, increased dimensions of the magnetic shields of the present invention may be required to attenuate EMI and RF fields, in addition to magnetic gauss fields, or when a sensitive device requiring protection is larger. MAGNET SHIELDING FOIL™, an 80% nickel alloy, was found to be the preferred alloy for attenuating residual magnetic fields of 10 G or less. It is very thin, easily cut, does not add substantial weight difference, and is most effective when provided with as a shield layer farther from a magnetic field comprising, for example, a layer of MAGNETSHIELD™ 0.015″, and a layer of MAGNET SHIELDING FOIL™. Such layering sequence prevents saturation of the MAGNET SHIELDING FOIL™, and improves the effectiveness of other, weaker shielding layers. GIRON™ was observed to be an effective magnetic field attenuator, but its added weight and inconsistent weave pattern must be further customized to intended applications. In some embodiments, GIRON™ is provided as sheeting rather than as a woven pattern, and/.or as a layer in a composite magnetic shield with lighter materials and coatings. Coatings, for example, Plasti Dip® were observed to improve the magnetic field attenuating capacity of magnetic shields. Present results indicate that: two 4″ MAGNETSHIELD™ 0.015″ discs, coated in Plasti Dip®, with added ⅛″ to ¼″ spacers, together with a 4″ disc of MAGNET SHIELDING FOIL™; 2 layers of 0.015″ MAGNETSHIELD™ 4″discs, coated in Plasti Dip®, a ¼″ spacer, a 4″ disc layer of MAGNET SHIELDING FOIL™, 2 layers of bamboo pads with VELCRO® 0.035″ thick; and one 4″ disc of 0.015″ MAGNETSHIELD™, and one layer of 4″ disc of MAGNET SHIELDING FOIL™ are each able to attenuate magnetic field strength to less than 5 G.

### Example 6

### Insulin Pump Magnet

Aim:

Magnetic closure magnets provided in, for example, insulin pump cases, may damage an insulin pump battery. For example, manufacturers advise that magnetic fields over 600 G may be harmful for insulin pumps. The present experiments were conducted to determine if magnetic closure cases marketed for use with, for example, insulin pump cases, emit magnetic fields over 600 G.

Methods:

The insulin pump tested (Insulin Pump Carrying Case/Pouch with Belt Clip/Belt Loops with Unique Designs (Small-A660: L3.65″×W2.25 . . . by A2Z4CELL (USA)) is an approximately 4″×2¾″ case with a belt clip on the back surface. Its cover flap comprises two ½″ diameter magnets. Peak gauss measurement s of the magnets were measured with a DC Gaussmeter Model 1-ST calibrated with a 500 G reference magnet. The cover flap was then closed and the corresponding location was determined that would align with magnets in the cover on the inside of the case. This location is in direct contact with the insulin pump. The gaussmeter sensor was then placed in direct contact with the surface closest to the magnet on the inside of the shield. The sensor tip was positioned directly against the front inside wall of the case to scan a ¾″ diameter area surrounding the corresponding magnet locations. The peak magnetic field strength was measured and recorded with a gaussmeter error margin of +/−1-2%. A magnet shield of the present invention was fabricated to fit the inside of the case. 0.015″ MAGNETSHIELD™ material was provided in a completed shield measuring 2″×3¾″ covered in GORILLA TAPE™ to blunt sharp edges. Corners of the magnetic shield were trimmed to match the pattern of the case.

Results:

Peak magnetic field levels measured on the inside of the top flap were 2054 G on the right side and 1998 G on the left side. When the case is closed, the peak field measurements observed on the front panel of the inside of the case are 613 G on the left side, and 616 G on the right side. Peak field magnetic field measurements with a magnetic shield of the present invention provided within the insulin pump case were less than 20 G.

Conclusions:

Whereas a magnet in the insulin pump case on the right side of the front closure flap has a peak field strength of 2054 G, a magnetic shield of the present invention inserted in the front inside of the case attenuates the field strength to less than 20 G. In some embodiments, a magnetic shield of the present invention comprises an insulin pump case with a magnet shield to attenuate unknown external environmental high field strength magnets in a convenient, attractive, and affordable format. In other embodiments, shielded insulin pump cases may also serve other purposes to attenuate magnetic fields form other sources and to shield other sensitive devices as, for example, belt-like holders for attachment on a user's upper chest, back, waist, or abdomen (e.g., MiniMed Sportguard™ Protective Case For Water Activities by Medtronic® MiniMed, Aquapac™ Waterproof Connected Electronics Case 558 by Aquapac™, and the like.)

### Example 7

### RFID Field Attenuation

Aim:

The aim of the present experiment was to determine if material layers added to magnetic shields block RFI from RFID emitters.

Methods:

Materials used comprised a new ViVOpay™ 4000 model#520-1133-12 reader, a ViVOtech® ViVOcard™ Contactless Test Card, a CORNET™ Microsystem ED-85EXS Electrosmog meter with a CORNET™ near-field probe attachment, diverse magnetic field and EMI/RFI blocking materials, and diverse EMI/RFI shielding fabrics. Table 11 provides ViVOpay™ RFID frequency and bandwidth specifications.

TABLE 11

| | | | Data | | Approximate tag |
|---|---|---|---|---|---|
| Band | Regulations | Range | speed | Remarks | cost in volume US $ |
| 13.56 MHz | ISM band | 10 cm-1 m | Low to | Smart cards | $0.50 |
| (HF) | worldwide | | moderate | (MIFARE, | |
| | | | | ISO/IEC 14443) | |

The ViVOpay™ 4000 RFID reader was activated and tested with a ViVOcard™ Contactless Test Card. The card was placed in direct contact with the face of the reader 10 times to assure accuracy. The ViVOpay™ system recognized the card and alerted its presence 10 out of 10 times. Material samples (Table 12.) were then placed over the card, and presented between the test card and the ViVOpay™ reader to determine their RFI blocking capacities. The card and test coverings were presented to the scanner 3 times to validate results.

TABLE 12

| | Test | | | Did it block the RFID signal? |
|---|---|---|---|---|
| | material | | | Y for positive results and N |
| Test material: | size: | Shielding: | Resistivity: | for negative results: |
| Pure Copper Taffeta | 1 12/16″ × | 80 dB | 0.05 Ohm/sq | Y |
| | 1 13/16″ | | | |
| RipStop ™ Silver | 1 14/16″ × | 60 dB | 0.3 Ohm/sq | N |
| | 1 14/16″ | | | |
| RadioScreen ™ | 1 13/16″ × | 50 dB | 0.1 Ohm/sq | Y |
| | 1 13/16″ | | | |
| Nickel Copper | 1 13/16″ × | 80 dB | <0.03 Ohm/sq | Y |
| RipStop ™ | 1 14/16″ | | | |
| CobalTex ™ | 1 13/16″ × | 80 dB | 0.01 Ohm/sq | Y |
| | 1 13/16″ | | | |
| Shieldit Super ™ | 1 14/16″ × | 60 dB | 1 Ohm/sq | Y |
| | 1 14/16″ | | (on 1 side) | |
| Peak Performance | 1 14/16″ × | 60 dB | <.5 Ohm/sq | N |
| Mesh | 1 13/16″ | | | |
| MAGNETIC | 4″ circle | MUMAX = | B(10OE) = | Y |
| SHIELDING | | 444000 | 7600G | |
| FOIL ™ | | | | |
| MAGNETSHIELD ™ | 4″ circle | 4000 | 21400 | Y |
| 0.015″ | | | Gauss | |
| MAGNETSHIELD ™ | 4″ circle | 4000 | 21400 | Y |
| 0.010″ | | | Gauss | |
| PaperSHIELD ™ | 4″ circle | N/A | N/A | Y |
| GIRON ™ | 4″ circle | AC or | 2.0 T | N |
| | | DC = 0-1000 Hz | | |
| Identity | 4″ × 5 | N/A | N/A | Y |
| StrongHold ™ | 2/16″ | | | |
| RFID blocker | | | | |
| SecureSleeve ™ | 2¼″ × 3½″ | N/A | N/A | Y |
| #1 in Service | | | | |
| All-Spec ™ Static | 4 14/16″ × 7 | N/A | N/A | N |
| Shielding Bag | | | | |
| REYNOLDS | 4″ circle | N/A | N/A | Y |
| WRAP ™ | | | | |
| Aluminum Foil | | | | |

A CORNET Electrosmog Meter Microsystem ED-85EXS with an attached CORNET near field probe was then used to obtain a measurement from the ViVOpay™ 4000. Surface measurements were conducted on the upper right corner of the pad i.e., over the surface of the screw. Peak measurements observed for each test material are shown in Table 13.

TABLE 13

| Test device and material | dBm measured |
|---|---|
| ViVOpay ™ 4000 | −.2 dBm |
| ViVOpay ™ 4000 w/ 0.010″ | −39.3 dBm |
| MAGNETSHIELD 4″ | |
| circular shield | |
| ViVOpay ™ 4000 w/ 0.014″ | −39.1 dBm |
| HyMu “80” ® 4″ circular | |
| shield | |
| ViVOpay ™ 4000 w/ 0.015″ | −44.7 dBm |
| MAGNETSHIELD 4″ | |
| circular shield | |
| ViVOpay ™ 4000 w/ | −15 dBm |
| GIRON ™ 4″ circular shield | |

Results:

The 0.014″ HyMu “80”® alloy was from a different source than the 0.015″ and 0.010″ MAGNETSHIELD™ alloys, this possibly accounted for the observed dBm value variance. The 0.010″, 0.014″, and 0.015″ HyMu80 and MAGNETSHIELD™, and the thinner MAGNET SHIELDING FOIL™, REYNOLDS WRAP™ Aluminum Foil, and ParerSHIELD™ metal or alloy based samples blocked RFI. GIRON™ was ineffective. Fabric samples comprising of Pure Copper Taffeta, RadioScreen™, Nickel Copper RipStop™, CobalTex™, and Shieldit Super™ were observed to be effective RFI attenuators, as were RFID sleeve and pouch products including Identity StrongHold™ RFID blocker, and SecureSleeve™ #1 in Service. The All-Spec™ Static Shielding Bag did not attenuate RFI satisfactorily, but in some embodiments is of value in attenuating static interference.

Conclusions:

Alloy components of magnetic shields of the present invention also effectively attenuate RFI and RFID electromagnetic interference. The dimensions of the shield must be sufficient to shield the area over which an RFID is in contact with a source or device. Use of fabrics for magnet shielding provide value when it is desired to add shielding from RFI. GIRON™ provided as a woven pattern is of limited use in applications wherein it is preferred for RFI to be attenuated.

### Example 8

### Magnetic Field Attenuation

Purpose:

The purpose of the present experiment was to test and compare a diversity of alloys, single and multiple layers, and coatings for magnetic field attenuation capacity.

Methods:

Nineteen magnetic shields of the present invention were tested by D.L.S Electronic Systems (Chicago, Ill.). Materials comprised a ½″ Neodymium magnet with a 1.5 kG center base measurement, a Lakeshore 410 Gaussmeter (Calibration due date Jan. 22, 2015), 0.015″ MAGNETSHIELD™, 0.014″ HyMu “80”®, GIRON™, ⅛″ Scotch™ Self Stick spacer with 2 layers to form ¼″ spacer, MAGNET SHIELDING FOIL™, Plasti Dip® (0.035″ coating thickness) coated 0.015″ MAGNETSHIELD™ 4″ Discs (total combined disc thickness of 0.05″), and 2 bamboo fabric pads with 3 single layer strips of VELCRO® sewn to one of the sides (total thickness including VELCRO® is 0.30″) (On the bamboo pad fabric samples, side 1 has three strips of VELCRO® and side 2 of the bamboo fabric covering does not have VELCRO®). Sample materials tested were marked with a center point. Measuring points A and B, or measuring points A, B, C, and D were marked 1″ from the geometric center of the alloy disc or composite shield in 4 quadrants, respectively i.e., either to the right and left of the center point, or to the right, left, top, and bottom of the center point. Magnetic field strength at the indicated measuring points were measured in sequence so that the sensor did not crossing over the center point with the magnet behind it. All measurements were made with the sensor directly touching the samples or magnet. The sensor was aligned in the same location of the horizontal line of the cross hairs of the center mark for consistency. For multiple layer testing, the test magnet was affixed to a table, and the center points were confirmed by measurements to assure that the test samples were aligned consistently with the magnet on the center point of the bottom layer. An example of one of the multiple layer shields that comprise fabric comprises a bottom layer of fabric, an alloy shield, a MAGNET SHIELDING FOIL™, a top layer of fabric, and a VELCRO® strip measured with the gaussmeter sensor tip placed directly against the upper surface. The center measurement of the top layer is measured with the gaussmeter sensor tip. Two samples of 0.015″ MAGNETSHIELD™ were measured to validate the consistency of the material. Diverse dimensions of alloy discs were tested to verify difference in measurements based on size. GIRON™ samples were tested to verify magnetic field attenuation of its weave pattern. Two sizes of GIRON™ shields were tested.

Results:

Table 14 shows the comparative magnetic field attenuation of diverse magnetic shield components and compositions.

TABLE 14

| | Test | | | Test | Test | Test | Test |
|---|---|---|---|---|---|---|---|
| Sample | Magnet | Center | | Point A | Point B | Point C | Point D |
| Sample 1-4″ disc GIRON ™ | 1.5 kG | 0.75 | kG | 7.2 G | 4.2 G | 5.2 G | 5.1 G |
| Sample 2-4½″ disc GIRON ™ | 1.5 kG | 0.72 | kG | 4.5 G | 3.4 G | 4.6 G | 4.6 G |
| Sample 3-4″ disc of 0.014″ | 1.5 kG | 1.15 | kG | 10 G | 8.8 G | | |
| HyMu “80” ® | | | | | | | |
| Sample 4-4″ disc of 0.015″ of | 1.5 kG | 0.61 | kG | 2.5 G | 2.4 G | | |
| MAGNETSHIELD ™-Sample 1 | | | | | | | |
| Sample 5-4″ disc of 0.015″of | 1.5 kG | 0.60 | kG | 2.1 G | 2.2 G | | |
| MAGNETSHIELD ™-Sample 2 | | | | | | | |
| Sample 6-5″ disc of 0.15″ | 1.5 kG | 0.61 | kG | 5.0 G | 4.5 G | 5.2 G | 4.3 G |
| MAGNETSHIELD ™ | | | | | | | |
| Sample 7-4″ disc of 0.015″ of | 1.5 kG | 0.43 | kG | 0.8 G | 3.6 G | 0.9 G | 1.5 G |
| MAGNETSHIELD ™ coated with | | | | | | | |
| Plasti Dip ®-side 1 | | | | | | | |
| Sample 8- 4″ disc of 0.015″ | 1.5 kG | 0.29 | kG | 0.8 G | 0.2 G | | |
| MAGNETSHIELD ™ coated with | | | | | | | |
| Plasti Dip ®-side 1 with a 4″disc | | | | | | | |
| of MAGNET SHIELDING | | | | | | | |
| FOIL ™ | | | | | | | |
| Sample 9-4″ disc of MAGNET | 1.5 kG | 0.35 | kG | 0.8 G | 0.3 G | | |
| SHIELDING FOIL ™ with 4″ | | | | | | | |
| disc of 0.015″ | | | | | | | |
| MAGNETSHIELD ™ Coated | | | | | | | |
| with Plasti Dip ® | | | | | | | |
| Sample 10- 4″ disc of 0.015″ | 1.5 kG | 9.0 | G | 1.7 G | 1.4 G | | |
| MAGNETSHIELD ™ coated with | | | | | | | |
| Plasti Dip ® with a 4″ disc of | | | | | | | |
| 0.015″ MAGNETSHIELD ™ | | | | | | | |
| Sample 1 | | | | | | | |
| Sample 11-4″ disc of 0.015″ | 1.5 kG | 19.5 | G | 4.2 G | 3.0 G | | |
| Sample 1 with 4″ disc of 0.015″ | | | | | | | |
| MagnetShield ™ coated with | | | | | | | |
| Plasti Dip ® | | | | | | | |
| Sample 12-2-4″ discs of 0.015″ | 1.5 kG | 9.0 | G | 3.0 G | 3.1 G | 3.0 G | 3.1 G |
| MAGNETSHIELD ™ coated with | | | | | | | |
| Plasti Dip ® | | | | | | | |
| Sample 13-2-4″ discs of 0.015″ | 1.5 kG | 6.8 | G | 3.5 G | 2.3 G | 2.2 G | 2.3 G |
| MAGNETSHIELD ® coated with | | | | | | | |
| Plasti Dip ® with ¼″ total height | | | | | | | |
| of space between discs with the | | | | | | | |
| spacers | | | | | | | |
| Sample 14- 2-4″ discs of Plasti | 1.5 kG | 2.3 | G | 2.4 G | 2.4 G | | |
| Dip ® with ¼″ spacers and a 4″ | | | | | | | |
| disc of MAGNET SHIELDING | | | | | | | |
| FOIL ™ | | | | | | | |
| Sample 15- The magnet, A layer | 1.5 kG | 6.2 | G | 1.4 G | 2.5 G | | |
| of BubuBibi ™ bamboo fabric | | | | | | | |
| without VELCRO ®-Side 2, a 4″ | | | | | | | |
| disc of disc of MAGNET | | | | | | | |
| SHIELDING FOIL ™, a 4″ disc | | | | | | | |
| of 0.015 MAGNETSHIELD ™ | | | | | | | |
| Sample 1, with a BubuBibi ™ | | | | | | | |
| bamboo fabric cover with | | | | | | | |
| VELCRO ®, measured on Side 1 | | | | | | | |
| with the sensor against the outer | | | | | | | |
| fabric layer with the VELCRO ® | | | | | | | |
| Sample 16- The magnet, A layer | 1.5 kG | 2.0 | G | 1.6 G | 2.2 G | | |
| of bamboo fabric layer with | | | | | | | |
| VELCRO ®-Side 1, a 4″ disc of | | | | | | | |
| 0.015″ MAGNETSHIELD ™ | | | | | | | |
| Sample 1, with a 4″ disc of | | | | | | | |
| MAGNET SHIELDING FOIL ™, | | | | | | | |
| covered with a bamboo fabric | | | | | | | |
| cover without VELCRO ®-Side | | | | | | | |
| 2, measured with sensor tip | | | | | | | |
| against the fabric without the | | | | | | | |
| VELCRO ®. | | | | | | | |
| Sample 17- The magnet, a layer | 1.5 kG | 6.0 | G | 2.0 G | 1.4 G | | |
| of bamboo fabric without | | | | | | | |
| VELCRO ®-Side 2, a 4″ disc of | | | | | | | |
| 0.015″ MAGNETSHIELD ™ | | | | | | | |
| coated with Plasti Dip ®, and a | | | | | | | |
| bamboo Fabric cover with | | | | | | | |
| VELCRO ® Side 1, measured | | | | | | | |
| with the sensor tip against Side 1 | | | | | | | |
| Sample 18-The magnet, a layer of | 1.5 kG | 6.3 | G | 1.8 G | 3.0 G | | |
| bamboo fabric with VELCRO ®- | | | | | | | |
| Side 1, a 4″ disc of 0.015″ | | | | | | | |
| MAGNETSHIELD ™ coated with | | | | | | | |
| Plasti Dip ®, with a bamboo | | | | | | | |
| fabric cover without VELCRO ®- | | | | | | | |
| Side 2. | | | | | | | |
| Sample 19-The magnet, a layer of | 1.5 kG | 1.8 | G | 1.7 G | 1.9 G | | |
| bamboo fabric with VELCRO ®- | | | | | | | |
| Side 1, a 4″ disc of 0.015″ | | | | | | | |
| MAGNETSHIELD ™ with Plasti | | | | | | | |
| Dip ®, a 4″ disc of MAGNET | | | | | | | |
| SHIELDING FOIL ™, and a | | | | | | | |
| bamboo fabric layer without | | | | | | | |
| VELCRO ®-Side 2. Measured | | | | | | | |
| with sensor tip on the center of | | | | | | | |
| Side 2. | | | | | | | |

Conclusions:

These results show that materials with less capacity to attenuate magnetic field strength benefit from proximity to material with greater capacity to attenuate magnetic field strength. Additional components of composite magnetic shields of the present invention, for example, Plasti Dip® coatings, and the BubuBibi™ bamboo fabric and VELCRO® coverings, further increase magnetic field attenuation. Larger shield dimensions provide greater magnetic field attenuation. A 0.015″ thickness of MAGNETSHIELD™ attenuates strong magnet fields more so than 0.014″ thickness HyMu “80”®. Spacers between layers of alloy provide further magnetic field attenuation, as does layering of heterogeneous materials. Deficits in GIRON™ magnetic shielding arising from its woven pattern may be addressed by its provision in unwoven sheets or in multiple layers to avoid weakness in the alloy.

### Example 9

### Magnetic Shield Wear and Deformation

Aim:

The aim of the present experiment was to measure the performance of magnetic shield materials and configurations after normal wear and daily use, and to determine the numbers of folds or manipulations that are necessary to damage a magnetic shield or attenuate its magnetic field shielding capacity.

Methods:

Materials used in the present experiments comprised two 4″ discs of alloy shielding material, a household chip clip with a central 817 G magnet, a magnetic shield covering comprising of two 4¾″ bamboo and water resistant pads, three 3″ to 4″×1″ strips of industrial strength VELCRO®, and a DC Gaussmeter Model 1-ST calibrated with a 500 G reference magnet.

A magnetic shield comprised a 4″ disc of alloy lined with duct tape and covered in 2 bamboo pads sewn together with three strips of VELCRO® sewn to the outside of the pads on one side. The completed magnetic shield was tested for G absorption capacity, and then used weekly for 52 weeks. The magnetic shield was provided inside the hats of a 2-year old user. The magnetic shield was tested at regular intervals throughout the year. After one year of use the magnetic shield was unchanged in G absorbing performance; at the beginning and end of the one year test interval, the magnetic shield attenuated the 817 G level of the test magnet to less than 10 G. No noticeable reduction in performance was observed.

In further experiments, a 4″ disc of 0.015″ MAGNETSHIELD™ alloy was marked with a center point and four additional points. These four points all measured 1″ from the geometric center of the disc in 4 quadrants, respectively. The points resembled the North, South, East and West directions of a compass. In this example A=North, B=East, C=South, and D=West. The additional measurement points were added to gain an accurate measurement variations arising from variations in the shape of the alloy caused by the bending and folding. These points are similar to those used with test samples in Example 8 above. The alloy materials were deformed in diverse directions by bending the sides of the magnetic shield up or down to no greater than a 20 degree angle from the center of the disc to the edges. Deformation was performed back and forth from the left to right sides for 50 cycles, and then back and forth on the top and the bottom of the disc for 50 cycles. The deformation cycles were completed 100, 200, and 300 times while placed in a bamboo pad covering case with the three VELCRO® strips. G absorption testing was performed on alloy magnetic shield discs before and after deformation. (Table 15.)

TABLE 15

| | | | Measurements of 817 G |
|---|---|---|---|
| | | | magnet and 4″ alloy disc, |
| | | Gauss measurement using | 1″ from center in 4 |
| | | an 817 gauss magnet | directions of A, B, C, and |
| | | covered by the 4″ Alloy | D. The magnet was also |
| | Alloy Disc | Disc. Center | relocated to be under |
| | Manipulations | Measurement. | these 4 additional points. |
| Test Sample | 0 manipulations | 64.5 G | 63, 66.7, 64.6, and 70 G |
| Sample 1 | 100 manipulations | 22 G | No measurements taken |
| Sample 2 | 200 manipulations | 18.5 G | No measurements taken |
| Sample 3 | 300 manipulations | 11.4 G | 11, 10, 9, and 18 G |
| Sample 4 | 300 <20 degree | 10.4 G | 6.7, 9.1, 6.6, 8.2 G * |
| | side bends and 25 | | |
| | >90 degree bends* | | |

Results:

It was not possible to fold the magnetic shield alloy discs to a breaking point with 300<20 degree edge bends, or an additional 25>90 bends and folds. The last 25 deformations were performed with the intent to break the alloy disc. To the contrary, the folds and ripples created made it difficult to continue folding, and impossible to fold the ripple ends together. After 325 manipulations, the alloy sample and covering were exposed directly to the 817 gauss magnet. The sample material measured 10.4 gauss in the center, 6.7 G at point A, 9.1 G at point B, 6.6 G at point C, and 8.2 G at point D. These points were all measured 1″ from the geometric center of the disc in 4 quadrants, respectively. All measurements were surprisingly superior (i.e., greater attenuation) to the measurements of the unbent control alloy disc. To further confirm the test results of Sample 4, two additional test measurements were made at the outer 1″ of the two remaining flatter edges. These measurements were 7.3 G and 9.6 G. The flattest portion of the folded disc was measured at 66.9 G consistent with the test sample. The greater the number of deformations and manipulations, the harder it was to bend the magnetic shield. Greater than 90° bends resulted in the alloy folding into an accordion-like shape, making it difficult to fold across the accordion ridges. Folding resulted in the dimensions of the disc shrinking from a 4″ diameter circle to a 4″ by 2.5″ shape with accordion like folds in the center. Gauss blocking measurements over the deformed disc were more inconsistent over the entire disc. However the peak measurement was identical to the baseline unbent measurement, while 85% of the measurements were lower in the deformed, pleated, folded discs. The unbent baseline sample disc had the highest center field strength measurement (i.e., lowest magnetic field attenuation). The bent/deformed magnetic shield test samples had lower center G measurements (i.e., greater attenuation) than baseline test sample. The bent samples 1, 2, 3, and 4 center measurements ranged from 6.2 to 2.9 times lower (i.e., greater attenuation) than the unbent sample.

Conclusions:

These results show that folding and deforming the magnetic shield alloy disc does not harm its shielding capacity, but to the contrary creates ridges and waves in the alloy disc that substantially lower (i.e., improve) the magnetic field attenuation. On deformed samples, flat spots near the edges measured unchanged from the baseline test sample. The more often the alloy disc was deformed, the harder it became to continue deformation i.e., the alloy disc loses pliability with increased frequency of deformation. Present observations indicate that the greatest risk to magnetic shield alloy discs of the present invention arise from 180° serial folds at a shared hinge site that would be very uncommon in daily intended use. Deformation that may be encountered in normal use, and in compliance with accompanying instructions, is unlikely to attenuate performance.

### Example 10

### Magnetic Shield Temperature Testing

Aim:

The aim of the present experiment was to test for changes in temperature of magnetic shields of the present invention with repetitive or continuous exposure to a magnetic field

Methods:

Materials used in the present experiments included a 2¾″ wide×⅝″ thick, ring-shaped, magnet with a minimum G measurement of 90 G at a distance of 1½″, a 4″ diameter disc of 0.015″ magnetic shield alloy metal, an Infrared Thermometer model HDE ST 380A, and a DC Gaussmeter Model 1-ST verified with a 500 gauss reference magnet. The ring-shaped magnet was placed in the center of the 4″ alloy disc. The disc with the magnet attached was then positioned on its side for testing. A gauss field absorption measurement was performed on the alloy before and after exposure to the strong magnet. The temperature of the alloy shield was monitored once a day for three days. The magnet was placed on the disc and not touched or moved for three days. Temperature measurements were taken from a fixed location at a distance of 8″s from the center of the metal.

Results:

Table 16. Provides disc temperatures (° F.) at 4 time intervals after continuous exposure of a magnetic shield of the present invention to a static magnetic field emitted by a permanent magnet.

TABLE 16

| Day | Temperature |
|---|---|
| 1 - Starting measurement | 76.5° F. |
| 2- 24 Hour measurement | 72.8° F. |
| 3- 48 Hour measurement | 75.9° F. |
| 4- 72 Hour measurement | 75.6° F. |

Conclusions:

Measured temperature variations were observed to parallel variations of ambient room temperature. No noticeable changes in temperature were observed. No changes in G absorption levels upon testing the magnetic shield alloy disc with the same magnet before and after 72 hour continuous magnetic field exposure were observed.

Although the invention has been herein described in what is perceived to be the most practical and preferred embodiments, it is to be understood that the invention is not intended to be limited to the specific embodiments set forth above. Rather, it is recognized that modifications may be made by one of skill in the art of the invention without departing from the spirit or intent of the invention and, therefore, the invention is to be taken as including all reasonable equivalents to the subject matter of the appended claims and the description of the invention herein. All publications and patents mentioned in the above specification are herein incorporated by reference.

What is claimed is:

1. A method of protecting a sensitive device from a magnetic or electromagnetic field source, comprising:
a) determining a magnetic or electromagnetic field strength threshold below which said device is not sensitive to said magnetic or electromagnetic field wherein said device is a worn or an implanted device;
b) determining a magnetic or electromagnetic field strength of said magnetic or electromagnetic field source wherein said magnetic or electromagnetic field source is a portable or household magnetic or electromagnetic field source;
c) selecting and sizing a magnetic or electromagnetic shield to shield said sensitive device from said magnetic or electromagnetic field source wherein said shield comprises an alloy; and
d) applying said shield to said magnetic or electromagnetic field source.

2. The method of claim 1, wherein said shield comprises a coating on said alloy.

3. The method of claim 1, wherein said shield comprises two or more alloy layers.

4. The method of claim 3, wherein said two or more alloy layers are separated by one or more spacers.

5. The method of claim 3, wherein said two or more alloy layers differ in shapes and dimensions.

6. The method of claim 3, wherein said two or more alloy layers differ in composition.

7. The method of claim 1, wherein said shield comprises a covering.

8. The method of claim 1, wherein said alloy is folded, pleated or corrugated.

9. The method of claim 1, wherein said shield is a magnetic or electromagnetic field source case.

10. The method of claim 1, wherein said determining a magnetic or electromagnetic field strength threshold below which said device is not sensitive to said magnetic or electromagnetic field comprises measuring said threshold, acquiring said threshold from a database, or acquiring said threshold from a device manufacturer.

11. The method of claim 1, wherein said determining a magnetic or electromagnetic field strength of said magnetic or electromagnetic field source comprises measuring said field strength, acquiring said field strength from a database, or acquiring said threshold from a field source manufacturer.

12. A method of protecting a sensitive device from a magnetic or electromagnetic field source, comprising:
a) determining a magnetic or electromagnetic field strength threshold below which said device is not sensitive to said magnetic or electromagnetic field wherein said device is a worn or an implanted device;
b) determining a magnetic or electromagnetic field strength of said magnetic or electromagnetic field source wherein said magnetic or electromagnetic field source is a portable or household magnetic or electromagnetic field source;
c) selecting and sizing a magnetic or electromagnetic shield to shield said sensitive device from said magnetic or electromagnetic field source wherein said shield comprises an alloy; and
d) positioning said shield between said sensitive device and said magnetic or electromagnetic field source.

13. The method of claim 12, wherein said shield comprises a coating on said alloy.

14. The method of claim 12, wherein said shield comprises two or more alloy layers.

15. The method of claim 14, wherein said two or more alloy layers are separated by one or more spacers.

16. The method of claim 14, wherein said two or more alloy layers differ in shapes and dimensions.

17. The method of claim 14, wherein said two or more alloy layers differ in composition.

18. The method of claim 12, wherein said shield comprises a covering.

19. The method of claim 12, wherein said alloy is folded, pleated or corrugated.

20. The method of claim 12, wherein said shield comprises a magnetic or electromagnetic field sensor and a visual and/or acoustic magnetic or electromagnetic field alert.

21. The method of claim 12, wherein said positioning comprises positioning said shield in a garment, in a pouch or sleeve, or on a lanyard.

22. The method of claim 12, wherein said determining a magnetic or electromagnetic field strength threshold below which said device is not sensitive to said magnetic or electromagnetic field comprises measuring said threshold, acquiring said threshold from a database, or acquiring said threshold from a device manufacturer.

23. The method of claim 12, wherein said determining a magnetic or electromagnetic field strength of said magnetic or electromagnetic field source comprises measuring said field strength, acquiring said field strength from a database, or acquiring said threshold from a field source manufacturer.

24. A method of protecting a sensitive device from a magnetic and an electromagnetic field source, comprising:
a) determining a magnetic and an electromagnetic field strength threshold below which said device is not sensitive to said magnetic and electromagnetic field wherein said device is a worn or an implanted device;
b) determining a magnetic and electromagnetic field strength of said magnetic and electromagnetic field source wherein said magnetic and electromagnetic field source is a portable or household magnetic and electromagnetic field source;
c) selecting and sizing a magnetic and electromagnetic shield to shield said sensitive device from said magnetic and electromagnetic field source wherein said shield comprises an alloy; and
d) positioning said shield between said sensitive device and said magnetic and electromagnetic field source.

25. The method of claim 24, wherein said determining a magnetic or electromagnetic field strength threshold below which said device is not sensitive to said magnetic or electromagnetic field comprises measuring said threshold, acquiring said threshold from a database, or acquiring said threshold from a device manufacturer.

26. The method of claim 24, wherein said determining a magnetic or electromagnetic field strength of said magnetic or electromagnetic field source comprises measuring said field strength, acquiring said field strength from a database, or acquiring said threshold from a field source manufacturer.

27. A method of protecting a sensitive device from a magnetic or electromagnetic field source, comprising:
a) selecting a magnetic shield wherein said shield reduces the magnetic or electromagnetic field strength of a magnetic or electromagnetic field source to a threshold below which said device is not sensitive to said magnetic and electromagnetic field; and
b) applying said shield to said magnetic or electromagnetic field source.

28. The method of claim 27, wherein said magnetic or electromagnetic field source is a permanent magnet, a computer, a cell phone, a smartphone, an audio source, a video source, a toy, a game, a learning aid, a musical instrument, a health care source, or a household appliance.

29. The method of claim 27, wherein said sensitive device is a sensitive neurologic device or a sensitive programmable neurologic device.

30. The method of claim 29, wherein said sensitive neurologic device is a ventriculo-peritoneal shunt, a vagal nerve stimulator, a deep brain stimulator, a spinal cord stimulator, or a neurologic electroencephalogram monitor.

31. The method of claim 27, wherein said sensitive device is a sensitive cardiac device or a sensitive programmable cardiac device.

32. The method of claim 31, wherein said sensitive cardiac device is a defibrillator, a cardio-verter, a ventricular assist device or a cardiac monitor.

33. The method of claim 27, wherein said sensitive device is an insulin pump, a drug infusion pump, a cochlear or hearing implant, or a prosthetic device.

34. A composition, comprising:
a) one or more layers of magnetic shield alloy;
b) one or more magnetic shield alloy coatings;
c) one or more magnetic shield coverings; and
d) one or more fasteners comprising two or more strips of plastic sheet wherein at least one strip provides loops and at least one strip provides flexible hooks, wherein said loop and hook strips removably adhere when pressed together.

35. The composition of claim 34, wherein at least one of said one or more layers of magnetic shield alloy is corrugated.

36. The composition of claim 34, further comprising e) a magnetic or electromagnetic field sensor.

37. The composition of claim 36, further comprising f) a magnetic or electromagnetic field alert.

38. The composition of claim 34, wherein the dimensions and shape of said composition are configured to protect a sensitive neurologic device, a sensitive programmable neurologic device, a ventriculo-peritoneal shunt, a vagal nerve stimulator, a deep brain stimulator, a spinal cord stimulator, a neurologic electroencephalogram monitor, a sensitive cardiac device, a sensitive programmable cardiac device, a defibrillator, a cardio-verter, a ventricular assist device, a cardiac monitor, an insulin pump, a drug infusion pump, a cochlear or hearing implant, or a prosthetic device.

39. The composition of claim 34, wherein the dimensions and shape of said composition are configured to shield a permanent magnet, a computer, a cell phone, a smartphone, an audio source, a video source, a toy, a game, a learning aid, a musical instrument, a health care magnetic or electromagnetic field source, or a household appliance.

40. The composition, comprising:
a) a wearable garment;
b) one or more layers of magnetic shield alloy;
c) one or more magnetic shield alloy coatings;
d) one or more magnetic shield coverings; and
3) one or more fasteners comprising two or more strips of plastic sheet wherein at least one strip provides loops and at least one strip provides flexible hooks, wherein said loop and hook strips removably adhere when pressed together.

41. A composition, comprising:
a) one or more layers of magnetic shield alloy;
b) one or more magnetic shield alloy coatings;
c) one or more magnetic shield coverings; and
d) a case for a magnetic or electromagnetic field source.

42. The composition of claim 41, wherein said magnetic field source is a permanent magnet.

43. The composition of claim 41, wherein said electromagnetic field source is a portable electronic electromagnetic field source.
